(19) United States
(12) Patent Application Publication
(10) Pub. No.: US 2026/0161858 A1
(43) Pub. Date: Jun. 11, 2026

(54) CLIMATE-CHANGE COMPENSATED, FLOOD-RISK EVALUATION SYSTEM AND METHOD

(71) Applicant: AT&T Intellectual Property I, L.P., Atlanta, GA (US)

(72) Inventors: Christopher Holle, Richardson, TX (US); Jessica Filante, NE Bainbridge Island, WA (US); Natalie Rodeghier, Dallas, TX (US); Christopher Bosma, Atlanta, GA (US); Emily Fashenpour, Dallas, TX (US)

(73) Assignee: AT&T Intellectual Property I, L.P., Atlanta, GA (US)

(21) Appl. No.: 18/971,312

(22) Filed: Dec. 6, 2024

(51) Int. Cl. G06F 30/28

(52) U.S. Cl. CPC G06F 30/28

(57) ABSTRACT

Aspects of the subject disclosure may include, for example, identifying climate data associated with a geographic region and comprising climate-adjusted precipitation data determined according to a climate model. Flood-depth data for the geographic region can be determined based on local terrain data and the climate-adjusted precipitation data. The flood-depth data can be converted to and/or otherwise classified according to a scoring methodology to obtain a flood depth risk metric that, in at least some instances, can be assigned a risk label. The risk metric and/or label can be presented to consumers according to a map, and in at least some instances, in the form of a recommendation to facilitate a planning activity within the geographic region. Other embodiments are disclosed.

### FIELD OF THE DISCLOSURE

The subject disclosure relates to a climate-change compensated, flood-risk evaluation system and method.

### BACKGROUND

Local storms with very high rainfall rates can give rise to surface flooding events, e.g., flash floods. These surface flooding events are referred to as pluvial flooding events, in which the rain overwhelms the ground's ability to absorb water, such that streets, buildings and/or other facilities may be inundated before any collecting storm water reaches a watercourse. Excess water flows overland can result in ponding at low-lying areas, which may be naturally occurring, man-made hollows and/or behind obstructions.

Weather forecasts may estimate anticipated rainfall associated with near-term weather patterns. However, changes in weather patterns, which may be attributable to a changing climate, may increase in frequency and intensity of heavy rainfall even, which may increase risks due to pluvial flooding. Warnings for pluvial floods are mostly limited to information on rainfall intensities and durations, which are typically provided over larger areas.

### BRIEF DESCRIPTION OF THE DRAWINGS

Reference will now be made to the accompanying drawings, which are not necessarily drawn to scale, and wherein:

FIG. 1 is a block diagram illustrating an exemplary, non-limiting embodiment of a communication system in accordance with various aspects described herein.

FIG. 2A is a block diagram illustrating an example, non-limiting embodiment of a flood-risk recommendation system functioning within the communication system of FIG. 1 in accordance with various aspects described herein.

FIG. 2B is a block diagram illustrating an example, non-limiting embodiment of a flood-risk evaluation system functioning within the communication system of FIG. 1 in accordance with various aspects described herein.

FIG. 2C is a block diagram illustrating an example, non-limiting embodiment of a flood-risk evaluation system functioning within the communication system of FIG. 1 in accordance with various aspects described herein.

FIG. 2D is a flood depth map illustrating an example, non-limiting embodiment of dynamically downscaled flood-depth input data to a flood-risk evaluation system of FIGS. 2A, 2B, 2C, functioning within the communication system of FIG. 1 in accordance with various aspects described herein.

FIG. 2E is a risk label map illustrating an example, non-limiting embodiment of a flood risk map determined by a flood-risk evaluation system of FIGS. 2A, 2B, 2C, based on the dynamically downscaled flood-depth input data, in accordance with various aspects described herein.

FIG. 2F depicts an illustrative embodiment of a flood-risk evaluation process in accordance with various aspects described herein.

FIG. 2G depicts another illustrative embodiment of a flood-risk evaluation process in accordance with various aspects described herein.

FIG. 2H depicts another illustrative embodiment of a flood-risk evaluation process in accordance with various aspects described herein.

FIG. 3 is a block diagram illustrating an example, non-limiting embodiment of a virtualized communication system in accordance with various aspects described herein.

FIG. 4 is a block diagram of an example, non-limiting embodiment of a computing environment in accordance with various aspects described herein.

FIG. 5 is a block diagram of an example, non-limiting embodiment of a mobile network platform in accordance with various aspects described herein.

FIG. 6 is a block diagram of an example, non-limiting embodiment of a communication device in accordance with various aspects described herein.

### DETAILED DESCRIPTION

The subject disclosure describes, among other things, illustrative embodiments for determining climate-compensated precipitation data, estimating flood depths of a region based on the precipitation data and local terrain data, classifying the flood depths according to risk scores to obtain a risk score map of the region. The risk scores and/or labels based on the risk scores, can be provided to inform facility planning and/or maintenance organizations of changing climate risks due to pluvial flooding. Other embodiments are described in the subject disclosure.

One or more aspects of the subject disclosure include a flood-risk evaluation system, that includes a processing system including a processor; and a memory that stores executable instructions. The executable instructions, when executed by the processing system, facilitate performance of operations. The operations include receiving dynamically downscaled climate data associated with a geographic region and including precipitation data determined according to a climate model. The operations further include receiving local topographical data of the geographic region and determining inundation depth data associated with the geographic region, based on the local topographical data and the precipitation data determined according to the climate model. The inundation depth data is classified according to a risk score to obtain a risk score map of the geographic region and a risk label map associated with the geographic region and based on the risk score map is assigned to the geographic location. The risk label map facilitates a facility planning activity of a facility located within the geographic region.

One or more aspects of the subject disclosure include a process of evaluating a flood risk. The process includes obtaining, by a processing system including a processor, dynamically downscaled climate data associated with a geographic region, with the climate data including precipitation data determined according to a climate model. The process further includes obtaining, by the processing system, terrain data of the geographic region. Inundation depth data associated with the geographic region is determined by the processing system, based on the terrain data and the precipitation data determined according to the climate model. The inundation depth data is scored by the processing system to obtain a risk score map of the geographic region. A risk label map associated with the geographic region and based on the risk score map, is assigned by the processing system, wherein the risk label map facilitates a facility planning activity of a facility located within the geographic region.

One or more aspects of the subject disclosure include a non-transitory machine-readable medium, including executable instructions that, when executed by a processing system including a processor, facilitate performance of operations. The operations include identifying dynamically downscaled climate data associated with a geographic region and comprising precipitation data determined according to a climate model. The operations further include obtaining terrain data of the geographic region and determining flood-depth data associated with the geographic region, wherein the flood-depth data is based on the terrain data and the precipitation data determined according to the climate model. The flood-depth data is evaluated according to a scoring methodology to obtain flood-depth risk data of the geographic region and risk label data is assigned according to the flood-depth risk data to obtain a risk label map, wherein the risk label map facilitates a planning activity within the geographic region.

Risk assessment of existing infrastructure and/or future infrastructure builds, typically relies on historical data. Climate change resulting from changes in the earth's atmospheric composition, temperature, surface and/or ocean temperatures and/or currents are increasingly changing weather patterns, including the severity of storms. In view of such changes, forward-looking data that models a future climate condition is essential for robust risk assessments and/or recommendations. Risk assessments related to investments and/or infrastructure can be used to determine where and/or how to build something as well as assessing the need to relocate existing infrastructure to a safer location. Existing climate risk scores for inland flooding include First Street Foundation's Flood Factor, which leverages statistically downscaled data rather than dynamically downscaled. Many localized flood analysis are also based primarily on fluvial flooding from rivers, lakes and other large bodies of water overflowing. The techniques disclosed herein address and/or otherwise integrate pluvial flood modeling. Pluvial flooding, also known as surface water flooding, is a type of flooding that occurs when heavy rainfall overwhelms the ground's ability to absorb water or a drainage system's capacity to manage it. Pluvial flooding events can occur in any location, even without nearby water bodies and may result from surface water floods and/or flash floods.

The techniques disclosed herein leverage newly developed climate data developed using a better methodology for capturing non-stationary trends than existing methods. The inland flood data may be difficult to interpret given that the flooding is represented as points on a relatively fine grid system, e.g., a 200-meter grid system, with each point representing a distribution and providing multiple return periods. In at least some embodiments, the techniques disclosed herein take into account terrain data, e.g., elevation data—an important factor in flooding, as well as climate trends, to obtain an inundation depth, or a flood depth as may be interpreted and/or otherwise processed to obtain a pluvial-based flood risk metric or score. For example, flood risk scores can be provided according to a predetermined scale, e.g., on a 1-10 scale, that makes it simple for engineers and planners to interpret results to make informed decisions.

It is understood that in at least some applications artificial intelligence, e.g., in the form of generative AI and/or machine learning can be leveraged to obtain one or more of the flood depth data, the flood risk scores, flood risk labels and/or recommendations related thereto. In at least some embodiments, the techniques disclosed herein, with or without AI, can evaluate optimizations, e.g., to obtain optimal solutions adapted to mitigate risk. Optimization may be based on one or more factors, such as cost, application of limited resources, schedule, and the like. Most previous approaches are focused on fluvial flood events from rivers, lakes, and the sea. The most common source of data for these fluvial events is FEMA's flood zone maps which are based on historical events and do not include pluvial flooding. As will be discussed further herein, other available weather related and/or flood related information, such as the FEMA flood maps, may be incorporated into one or more process steps in performing the flood risk evaluations.

The systems, devices, processes and/or software disclosed herein include a climate-change, and/or a climate-change adjusted, flood risk scoring methodology that can translate dynamically downscaled climate data into actionable risk data, i.e., scores. The resulting risk scores can improve long-term decision making and planning for future pluvial flood potential, as well as improving readiness for short-term weather events in view of a changing climate. Wide view, e.g., national and/or global climate data can be regionalized and/or localized, e.g., by processes known as dynamic downscaling and/or statistical downscaling. In at least some embodiments, dynamic downscaling applies outputs obtained from a global climate model as inputs to a separate, high-resolution regional climate model. A significant difference compared to statistical downscaling, is that dynamic downscaling accounts for the physical processes and natural features of a region, as well as the complex interaction between these elements and global dynamics under a climate scenario. It is generally understood that dynamically downscaled climate data can provide the precipitation data, the flood depth data and/or any resulting risk scores an improved picture of what the future might hold. A perceived value of the risk scores comes from an ability to plan infrastructure with future flood conditions in mind, and particularly in view of a climate that is changing according to processes, such as greenhouse gas emissions. The resulting risk scores can lead to cost savings from reduced damage and/or improved safety. With computation power improving and innovations in the climate modeling space, the techniques disclosed herein can be extended to other platforms and/or implementations in the future as more resources are made available.

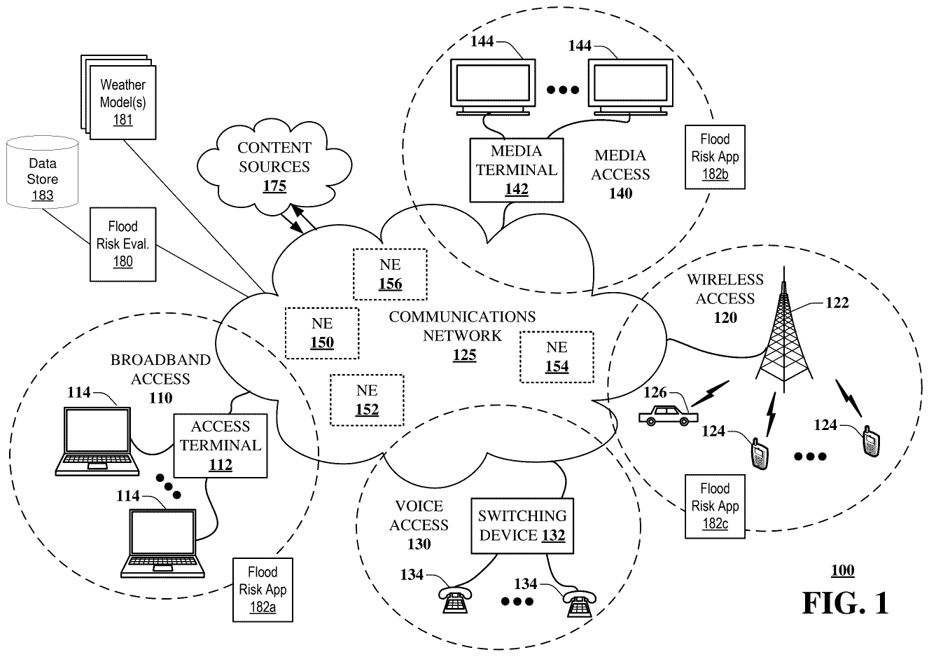

Referring now to FIG. 1, a block diagram is shown illustrating an example, non-limiting embodiment of a communication system 100 in accordance with various aspects described herein. For example, the communication system 100 can facilitate in whole or in part determining climate-compensated precipitation data, estimating inland flood depths of a region based on the precipitation data and local terrain data, and classifying the inland flood depths according to risk scores to obtain a risk score map of the region. The risk scores and/or labels based on the risk scores can be shared with facility planning and/or maintenance organizations to inform them of pluvial flood risks associated with changing climate conditions. The classified risk scores and/or labels are easily interpretable to inform planners of short and/or long-term events.

In particular, a communications network 125 is presented for providing broadband access 110 to a plurality of data terminals 114 via access terminal 112, wireless access 120 to a plurality of mobile devices 124 and vehicle 126 via base station or access point 122, voice access 130 to a plurality of telephony devices 134, via switching device 132 and/or media access 140 to a plurality of audio/video display devices 144 via media terminal 142. In addition, communication network 125 is coupled to one or more content sources 175 of audio, video, graphics, text and/or other media. While broadband access 110, wireless access 120, voice access 130 and media access 140 are shown separately, one or more of these forms of access can be combined to provide multiple access services to a single client device (e.g., mobile devices 124 can receive media content via media terminal 142, data terminal 114 can be provided voice access via switching device 132, and so on).

The communications network 125 includes a plurality of network elements (NE) 150, 152, 154, 156, etc., for facilitating the broadband access 110, wireless access 120, voice access 130, media access 140 and/or the distribution of content from content sources 175. The communications network 125 can include a circuit switched or packet switched network, a voice over Internet protocol (VoIP) network, Internet protocol (IP) network, a cable network, a passive or active optical network, a 4G, 5G, or higher generation wireless access network, WIMAX network, UltraWideband network, personal area network or other wireless access network, a broadcast satellite network and/or other communications network.

In various embodiments, the access terminal 112 can include a digital subscriber line access multiplexer (DSLAM), cable modem termination system (CMTS), optical line terminal (OLT) and/or other access terminal. The data terminals 114 can include personal computers, laptop computers, netbook computers, tablets or other computing devices along with digital subscriber line (DSL) modems, data over coax service interface specification (DOCSIS) modems or other cable modems, a wireless modem such as a 4G, 5G, or higher generation modem, an optical modem and/or other access devices.

In various embodiments, the base station or access point 122 can include a 4G, 5G, or higher generation base station, an access point that operates via an 802.11 standard such as 802.11n, 802.11ac or other wireless access terminal. The mobile devices 124 can include mobile phones, e-readers, tablets, phablets, wireless modems, and/or other mobile computing devices.

In various embodiments, the switching device 132 can include a private branch exchange or central office switch, a media services gateway, VoIP gateway or other gateway device and/or other switching device. The telephony devices 134 can include traditional telephones (with or without a terminal adapter), VoIP telephones and/or other telephony devices.

In various embodiments, the media terminal 142 can include a cable head-end or other TV head-end, a satellite receiver, gateway or other media terminal 142. The display devices 144 can include televisions with or without a set top box, personal computers and/or other display devices.

In various embodiments, the content sources 175 include broadcast television and radio sources, video on demand platforms and streaming video and audio services platforms, one or more content data networks, data servers, web servers and other content servers, and/or other sources of media.

In various embodiments, the communications network 125 can include wired, optical and/or wireless links and the network elements 150, 152, 154, 156, etc., can include service switching points, signal transfer points, service control points, network gateways, media distribution hubs, servers, firewalls, routers, edge devices, switches and other network nodes for routing and controlling communications traffic over wired, optical and wireless links as part of the Internet and other public networks as well as one or more private networks, for managing subscriber access, for billing and network management and for supporting other network functions.

According to the illustrative embodiment, the communication system 100 includes a flood risk evaluation system 180 configured to estimate inland flood depths of a region based on climate-compensated precipitation data, in view of local terrain data, and to classify the flood depths according to risk scores to obtain a risk score map of the region. To the extent the flood risk evaluation system 180 relies upon one or more supporting systems 181, such as database systems and/or models, the supporting systems 181 may be accessible via the communication network 125. Alternatively, or in addition, at least some of the supporting systems 181 may be incorporated into the flood risk evaluation system 180 and/or otherwise locally accessible. Supporting systems 181 may include, without limitation, any of the various supporting systems disclosed herein and/or otherwise generally known, such as weather models, climate models, physics models, hydrologic models, water cycle models, flood-risk models and so on.

The example risk scores and/or labels based on the risk scores disclosed herein can be shared with facility planning and/or maintenance organizations to inform them of pluvial flood risks associated with changing climate conditions. In at least some embodiments, the communication system 100 further includes a data store 183 that may include a data storage system or device, e.g., a network drive and/or a database. At least a portion of the data store 183, when utilized, may be provided locally to the flood risk evaluation system 180. Alternatively, or in addition, at least a portion of the data store 183 may be remote from the flood risk evaluation system 180, e.g., accessible via the communication network 125.

In operation, it is understood that the flood risk evaluation system 180 may include a processing system including a processor and a memory storing executable instructions to perform flood risk evaluation related functionality. Examples include, without limitation, generating and/or obtaining dynamically downscaled climate data including climate-compensated precipitation data, estimating inland flood depths of a region based on the climate-compensated precipitation data, in view of local terrain data, and/or classifying the flood depths according to risk scores to obtain risk scores, e.g., int the form of a risk score map of the region. Alternatively, or in addition, the functionality may be configured to generate labels associated with the risk scores, e.g., according to a label map of the region and/or recommendations, as may be applicable to facility planning and/or operation and maintenance. Recommendations can include long-term recommendations, such as recommended locations for installing and/or expanding equipment of an operational facility. Alternatively, or in addition, recommendations can include short-term recommendations, such as recommendations related to preparing for an imminent weather, i.e., flooding, event, e.g., by recommending whether sandbagging may be advisable based on a risk score related to a projected or forecasted climate-compensated flood depth.

In some embodiments, the flood risk evaluation system 180 may produce output in the form of reports, e.g., a flood-depth risk score report, a flood-depth risk score map, a flood-depth label report, flood-depth label map, recommendations and the like. In at least some embodiments the scores, labels and/or recommendations may be agnostic, at least in that they don't relate to a particular application and/or business sector. Alternatively, or in addition, one or more of the scores, labels and/or recommendations may be determined according to a particular application and/or business sector and/or otherwise translated from agnostic data, in order to facilitate consumption by facility planners and/or operations and maintenance organizations of a particular application and/or business sector. It is envisioned that in such instances, a risk evaluation methodology may consider one or more aspects of a particular application or business sector, as may be relevant in determining a risk score, a risk value, and/or a risk range. By way of example, a particular application and/or business sector may be understood to utilize certain types of facilities, e.g., environmentally controlled facilities, equipment cabinets, towers, battery backup power systems, diesel backup power systems, buried systems, and so on. Each type of facility may present a unique risk and/or class of risks related to flood depths and/or durations.

It is further envisioned that reporting information produced by the flood risk evaluation system 180 may be distributed, posted and/or otherwise made available to consumers of the various reporting content. To this end, the flood risk evaluation system 180 may include a web-accessible portal as may be accessed from one or more of the data terminals 114, the display devices 144 and/or the mobile devices 124, e.g., by way of a browser application. Alternatively, or in addition, one or more application programs 182a, 182b, 182c, generally 182, may be distributed and/or otherwise made available to one or more of the data terminals 114, the display devices 144 and/or the mobile devices 124, to facilitate access to reporting information produced by the flood risk evaluation system 180. Alternatively, or in addition, one or more of such web portals and/or application programs 182 can include a user interface configured to enable interaction with one or more of the flood risk evaluation system 180, the data store 183 and/or the supporting systems 181. For example, it is envisioned that a user, e.g., a mobile user, may utilize a mobile application program 182c to request flood risk scores, labels and/or recommendations based on a user supplied region as may be identified by geocoordinates, a residential or business address, and/or some other reference, such as a town or county. Alternatively, or in addition, the user may request a flood risk evaluation for user identified location and/or an updated flood risk evaluation of a previously determined flood risk score and/or label map. It is understood that in at least some embodiments, the user interface can include a graphical user interface configured to display map content, such as topological maps, geopolitical maps, flood depth maps, risk score maps, risk score label maps, and the like.

It is envisioned that one or more of the flood risk evaluation system 180, the data store 183 and/or the supporting systems 181 may be embodied in respective system components that may be localized and/or distributed and/or otherwise accessible via the communication network 125. Alternatively, or in addition, it is understood that a portion or all of any one or more of the flood risk evaluation system 180, the data store 183 and/or the supporting systems 181 may be incorporated into the communication network 125, e.g., in one or more of the example network elements 152.

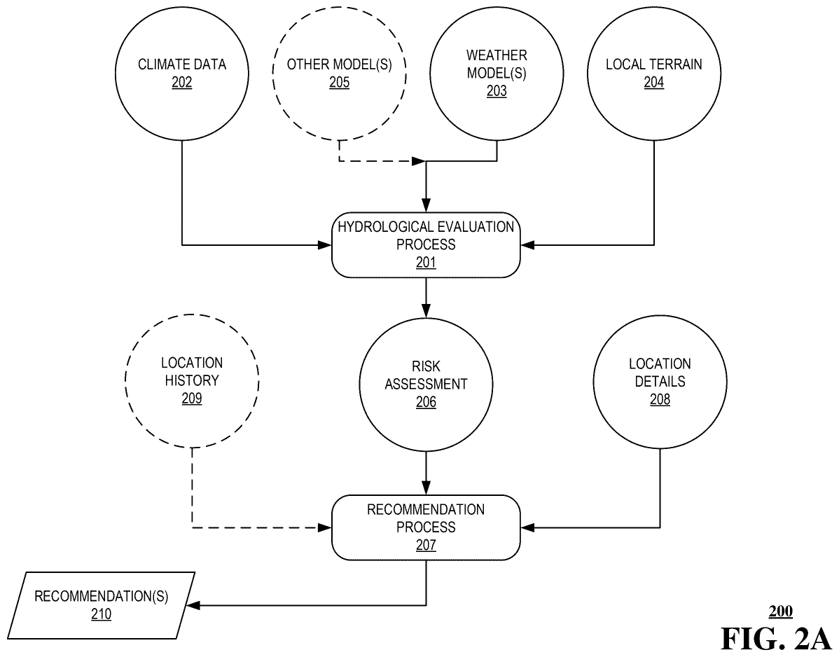

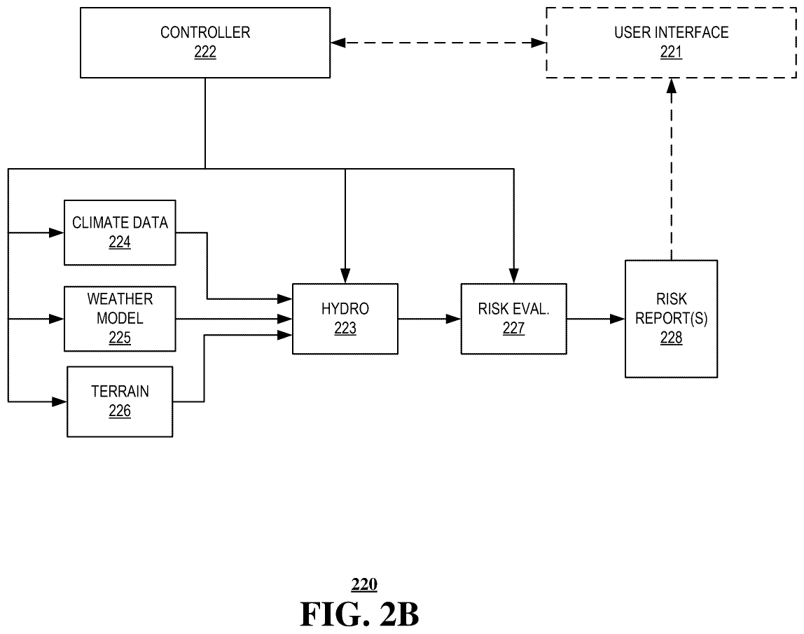

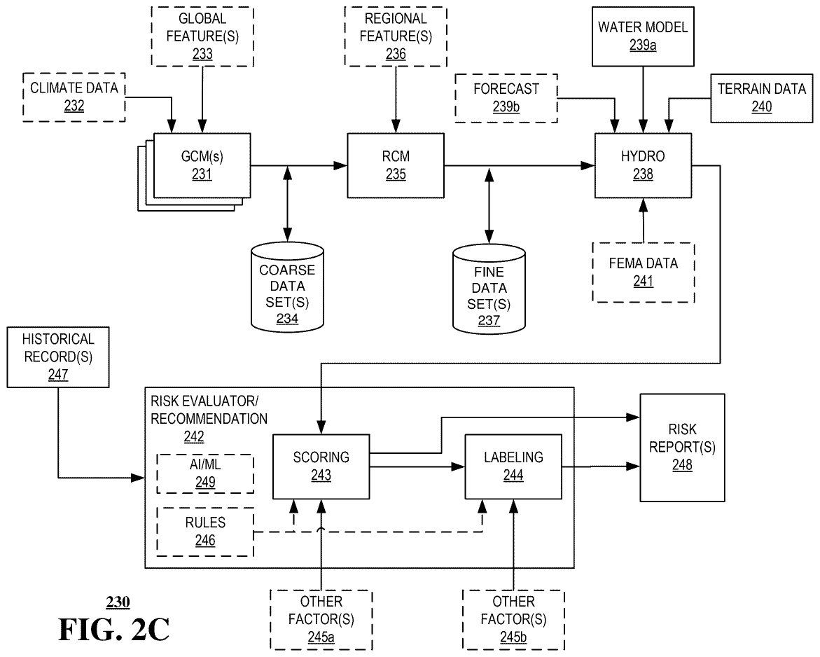

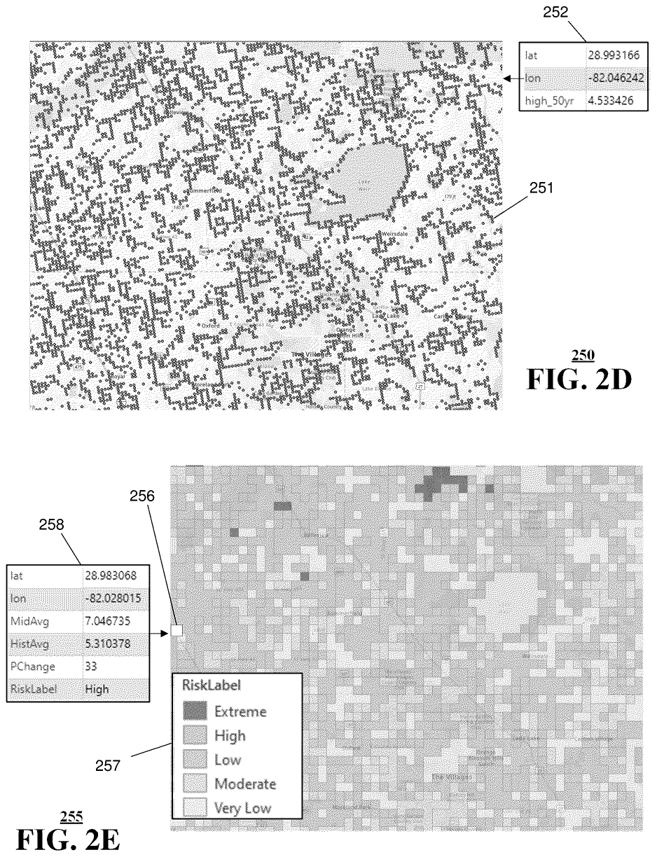

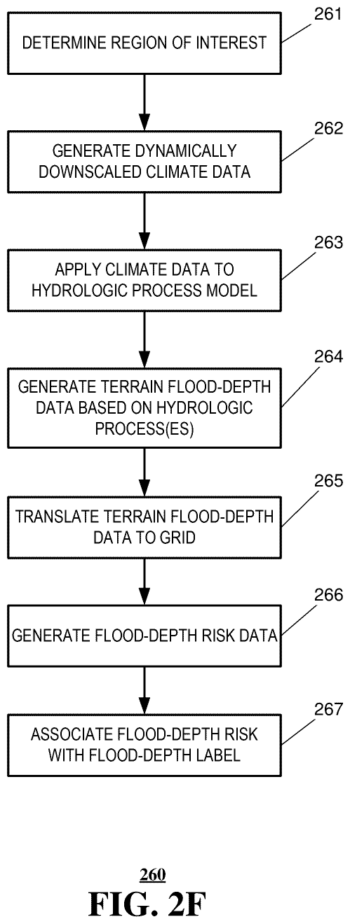

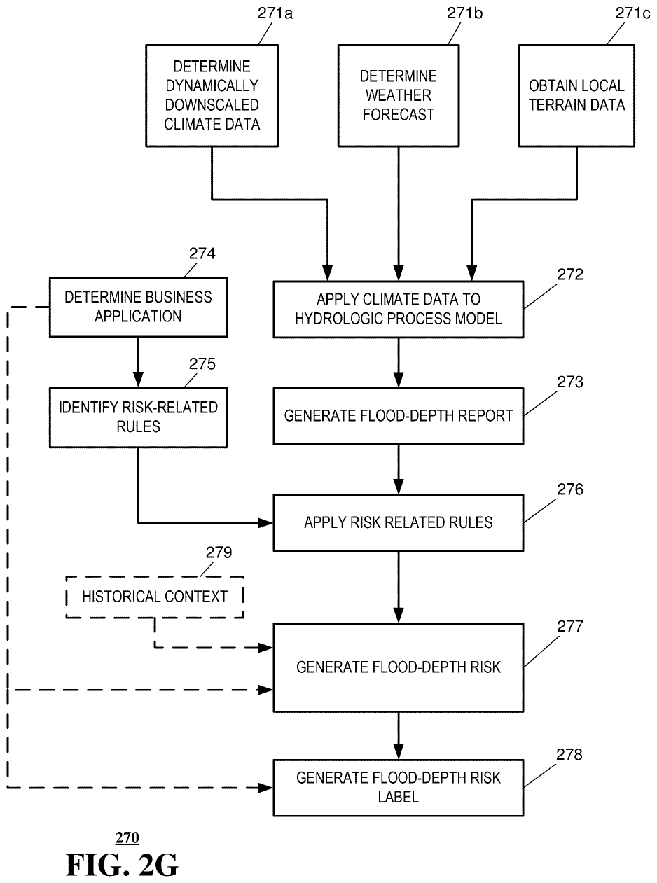

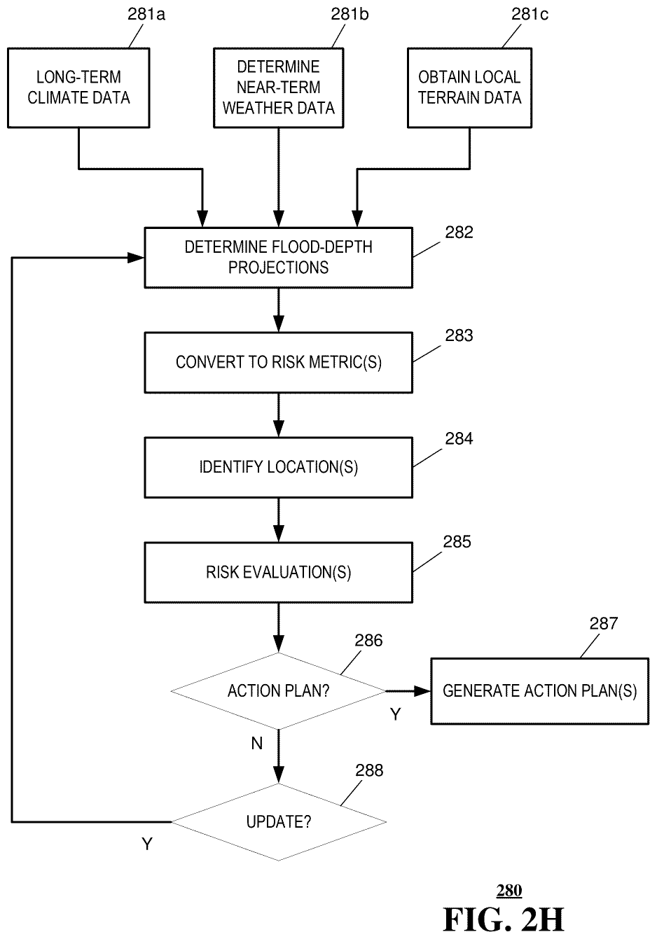

FIG. 2A is a block diagram illustrating an example, non-limiting embodiment of a flood-risk recommendation system 200 functioning within the communication system of FIG. 1 in accordance with various aspects described herein. The example flood-risk recommendation system 200 includes a hydrological evaluation process module 201 configured to provide inland flood estimate data. The hydrological evaluation process module 201 is in communication with one or more of a climate data process module 202, a weather model 203, a local terrain model and in at least some embodiments, one or more other process modules 205. One or more of the climate data process module 202, a weather model 203, a terrain data source 204 and in at least some embodiments, one or more other process modules 205 provide input data to the hydrologic evaluation process module 201 as may be utilized to obtain and/or otherwise adjust output data, such as the example inland flood estimate data.

In at least some embodiments, the climate data process module 202 can be configured to provide past, present and/or future weather estimates based on configurable climate conditions. The climate conditions can include, without limitation, land and/or sea temperatures, e.g., surface temperatures, ocean current information, atmospheric composition data, e.g., concentrations of greenhouse gases and so on. Without limitation, weather estimates provided by the climate data process module 202 can include precipitation estimates based on one or more climate scenarios. For example, precipitation data predictions may be obtained every three hours over a continuous reporting period, such as a preceding 50-year period, a projected 50-year period and/or a projected 100-year period. The greenhouse gas composition for future predictions may be determined according to an estimated changing composition, e.g., an increase in greenhouse gases according to one or more scenarios. At least one such scenario is referred to as “business as usual” and includes increasing concentrations of greenhouse gas emissions over the forecast period(s). The predictions may be summarized, e.g., averaged to obtain one or more of daily averages, weekly averages, monthly averages, seasonal averages, yearly averages and/or long-term averages. In at least some embodiments, the predictions and/or the average may arranged to determine worst case events, such as worst case predictions, such as worst case hourly averages, worst case daily averages, and so on.

Climate data process module 202 can model one or more of aerosol-cloud interactions, aerosol chemistry and transport, and radiating forcing in the atmosphere. These conditions can be incorporated into atmospheric models to obtain meteorological assessments. Examples of climate data process module 202 include models available from the Argonne National Laboratory. These models provide high-resolution regional-scale climate models, e.g., 12 km resolution, that evaluate climate change impacts on hydrology and ecology. It has been reported that the model results are better at forecasting seasonal features and extreme weather events than previous models, adding accuracy to climate predictions.

It is recognized a much finer resolution is required to provide meaningful assessment of inundation depths or flood depths suitable for applications in facility planning and/or local government planning efforts. Preferably, the resolution is sub kilometer, e.g., a 600-meter resolution, a 200-meter resolution, and even finer resolutions below 200-meters. It is understood that in at least some embodiments, the climate data process module 202 may be configured to provide climate-adjusted meteorological data, such as precipitation data, at a relatively course resolution, e.g., greater than about a 600-meter resolution. In such instances, at least one of the other model process modules 206 can be configured to perform a down-scaling of the relatively coarse climate-adjusted meteorological data to obtain a finer resolution representation of the relatively coarse resolution climate-adjusted meteorological data. In some embodiments, the downscaling can be accomplished according to a statistical process. For example, the results determined according to a relatively coarse grid may be interpolated to obtain estimated results over a relatively fine grid. Alternatively, or in addition, the downscaling can be accomplished in a dynamic manner, referred to as dynamically down-scaling the climate-adjusted meteorological data. It is understood that in at least some embodiments, the dynamically down-scaling process may take into account modeling of the same physical processes as performed to obtain the coarse model, but over a smaller and/or more localized region. In such instances, the coarse results may be used as boundary conditions and/or forcing function in conjunction with the dynamically down-scaling process. It is recognized that the dynamically down-scaling process when compared to statistically downscaling, requires a greater cost in terms of computation and complexity. In view of this, each approach offers their own benefits and applications. For example, the dynamically downscaled data may be better suited for localized flood analysis, because they include the non-stationarity of the climate, whereas statistical approaches assume stationary trends. In at least some embodiments, the dynamically downscaled data is obtained from another source and provided as an input to the hydrological evaluation process module 201.

The terrain data source 204 provides local terrain data to the hydrological evaluation process module 201. By way of illustrative example, the local terrain data may include topological data indicative of a surface of the land, e.g., elevations and/or land formations. The hydrological elevation process module 201 may combine the topological data with precipitation data obtained from the climate data process module 202 to obtain estimates of surface water flow and/or pooling as may result from precipitation. Alternatively, or in addition, the terrain data source 204 can provide other terrain data identifying physical characteristics of the local area that may be relevant to inundation modeling and/or calculations of flood depth estimates. For example, the local terrain data may include soil information, e.g., soil type and/or moisture content. It is understood that a soil type, e.g., clay versus sand, and/or moisture content, e.g., saturated versus dry, may affect inundation modeling and/or calculations of flood depth estimates. Still other terrain features can include, without limitation, vegetation, land use, e.g., farmland, versus forest, versus urban landscapes.

In at least some embodiments, the weather models 203 can include one or more of various weather evaluations, predictions and/or forecasting models. At least some of the weather models 203 can be configured to forecast water cycles. For example, the NOAA National Water Model simulates a water cycle with mathematical representations of different physical processes and how they fit together, e.g., snowmelt and infiltration and movement of water through soil layers as may vary with elevations, soils, vegetation, etc. Other weather models can include, without limitation, weather forecasting models based on recent past, current and predicted atmospheric conditions as used in weather apps and by meteorologists in preparing weather forecasts. The weather model may provide hourly forecasts for a current day and/or daily forecasts extending into the future. Such future forecasts based on current observations and recent past conditions are generally extendable to about two weeks before becoming unreliable. Such weather forecasts may include one or more of temperature, winds cloud cover, and/or precipitation.

In at least some embodiments, the flood-risk recommendation system 200 includes a risk assessment process module 206. The example risk assessment process module 206 is in communication with the hydrological evaluation process module 201. The risk assessment process module 206 can receive one inundation depth data, e.g., flood depth data, from the hydrological evaluation process module 201. In at least some embodiments, the flood depth data includes estimates of flood depts at various locations occurring within a localized region, e.g., a region of interest as may be determined according to an example scenario in which recommendations are sought for the localized region. The localized region may encompass one or more facilities of interest, such as a neighborhood, a town, one or more particular buildings, e.g., an apartment complex, a business campus and/or an educational facility, a telecommunication equipment facility, a radio tower, and so on. In at least some embodiments, the flood depths may be provided in a data layer that can be overlaid upon a geographic map, e.g., a terrain map and/or a facility map. The flood depth data may be evaluated and/or otherwise provided a points that may lie upon a grid. Alternatively, or in addition, the flood depth data points may not be aligned with a grid corresponding to the geographic map, but perhaps another grid and/or no grid at all.

The risk assessment process module 206 can be configured to apply a risk assessment methodology to obtain a measure of risk associated with flood depths and/or a range of flood depths. It is envisioned that in at least some scenarios, the risk assessment methodology can be agnostic, e.g., in that it is not based upon a particular application, type of facility, and/or consumer of the related risk evaluation data. For example, the risk assessment methodology may determine a flood depth range between some minimum flood depth FD_{MIN}, e.g., zero, to some maximum, e.g., a maximum flood depth as may be determined according to the hydrological evaluation process module 201. In such instances, a risk scale can be assigned to the flood depth range. For example, if a worst-case predicted flood depth within a region is FD_{MAX}, then a difference between the maximum and minimum flood depths, i.e., FD_{MAX}−FD_{MIN} can be associated with a risk scale, e.g., a scale of 0-N. The scale can be linear, such that differences between adjacent score values correspond to a delta flood depth, ΔFD, determined as:

ΔFD=[FD_{MAX}−FD_{MIN}]/N Eq. 1

Alternatively, or in addition, the scale can be related to a range of flood depths according to some other relationship, e.g., quadratic, logarithmic, etc. In at least some embodiments, the scale may be determined according to risk factors, such that a numeric rating may relate to a predetermined range of flood depths. For example, 0-1 inch may be associated with a risk score of 1 on a scale of 1-10. Similarly, 1-2 inches may be associated with a risk score of 2, 3-6 inches may be associated with a risk score of 3, up to a flood depth of greater than 6 feet being associated with a risk score of 10. Alternatively, or in addition, the risk assessment methodology may be based on an application and/or some other relevant factor as may be used to correlate flood depths and/or flood depth ranges to particular risk severities. For example, the flood depth may be correlated to a damage category and/or equivalent economic impact. A flood depth below 1 inch may damage floors, but not much else, while a flood depth of a few inches may damage walls and/or equipment as may be hosted in equipment racks, and so on.

The risk assessment process module 206 can be configured to provide a risk score based on flood depth data received from the hydrological evaluation process module 201. In some embodiments, the risk scores are provided at risk assessment points that may lie upon a grid. For example, the risk assessment points may coincide with grid points of the flood depth data received from the hydrological evaluation process module 201. Alternatively, or in addition, the flood depth data points may not be aligned with a grid corresponding to the geographic map, but perhaps another grid and/or no grid at all. In at least some embodiments, the flood depth data grid points may be translated to another grid, e.g., a uniform grid associated with a terrain map, such that the risk assessment points are obtained according to the same translated grid. In at least some embodiments, the risk assessment points coincide with the flood depth data points, being translated to the uniform grid points after having had a risk assessment performed.

In some embodiments, the risk assessment process module 206 may determine a numeric score, while in other embodiments it may determine an alphanumeric score, and/or some other visual indicator, such as shade of gray, color, and/or some other fill pattern as may be used to distinguish different risk severities, e.g., greater risks reflected as darker shaded areas of the risk assessment map overlay.

In at least some embodiments, the risk assessment process module 206 can be configured to determine a risk severity label. For example, the risk assessment process module 206 may determine a risk label of low, medium or high. The risk labels can be determined at least in part according to a direct translation form a risk score, e.g., risk scores of 0-3 being assigned a risk label of “low,” while risk scores of 4-7 are assigned a risk label of “medium” and risk scores of 8-10 are assigned a risk label of “high.” Alternatively, or in addition, a translation from a risk score to a risk label may be based at least in part upon data other than the risk score. For example, risk labels may be determined at least in part based on an application to which a risk assessment is applied. Thus, a risk for sensitive electronic equipment as may be used in a high-reliability communications facility may be assigned high risk according to one evaluation, e.g., any scores above 3 are labeled high risk, and/or any flood depths above 3 inches are labeled high risk. This can be contrasted to a vehicle storage facility, e.g., a parking lot or garage, in which flood depths below 6 inches may be considered a low risk. In at least some embodiments, a determination of risk labels is based on the risk score alone, the flood depth alone, or a combination of the risk score and the flood depth.

In at least some embodiments, the flood-risk recommendation system 200 includes a recommendation process module 207. The recommendation process module 207 can be configured to provide a recommendation based upon one or more of a risk score, a risk label, a flood depth or any combination of a risk score, a risk label and flood depth data. In at least some embodiments, the recommendation process module 207 provides actionable recommendations that when followed to in a timely manner can mitigate flood damage. For example, the recommendation may be to move equipment to a different facility, to turn off electrical power and/or natural gas lines, to perform sandbagging, or to do nothing, and so on. Other recommendations may be informative, e.g., suggesting resource allocation for a disaster response. Without limitation, resources may include hardware, such as pumps and/or backup power generators, and/or positioning of personnel, such as technicians and/or safety personnel. Other recommendations may include informing a network operator, an electrical power grid operator, and/or a municipality as to what locations would benefit from redundancy and/or infrastructure diversification to handle outages. Still other recommendations may include informing businesses, first responders, government organizations and/or residents regarding evacuations and/or prioritization of personnel at likely flood-affected locations.

It is understood that any recommendations, including the various examples discussed herein, may be provided according to a relatively short-term schedule, e.g., in advance of an imminently forecasted weather event. Alternatively, or in addition, the recommendations may be provided according to a mid-term schedule, e.g., in advance of an anticipated seasonal variation such as a winter and/or a rainy season. In at least some applications, the recommendations can be provided for longer-term schedule, e.g., for long-term considerations in terms of years or even decades as may affect facility planning and/or long-term municipal preparedness planning.

By way of further examples, the recommendations may inform resource allocation for disaster response and/or inform evacuation efforts and/or personnel prioritization. Still other recommendations may inform what locations require redundancy and/or infrastructure diversification to handle outages. Further examples include information and/or recommendations regarding placement generators for backup power preparedness and/or placement of water barriers, such as sandbags and/or more permanent structures, such as flood gates. Still other examples may include recommendations of equipment elevations, e.g., based on criticality and/or susceptibility. Thus, the recommendations can provide guidance on a short-term basis by recommending a repositioning and/or reorganization of resources as may be available to avoid and/or otherwise minimize susceptibility to a flood event. Alternatively, or in addition, the recommendations can provide guidance on a longer-term basis as may be beneficial for construction planning and/or building design and facility planning as may be used for planned construction, renovation and/or remodeling.

It is understood further that the techniques disclosed herein can be applied as a matter of course to construction design and/or planning efforts. Such design and planning based solely on legacy information, such as FEMA flood zone designations, may prove inadequate in view of uncertainty introduced by a changing climate. According to the techniques disclosed herein, impacts resulting from climate change can be incorporated into predictions and/or forecasts, including pluvial flood estimates. The resulting predictions and/or forecasts can include long-term estimates, such as worst case 50 to 100-year events in view of informed and/or otherwise selectable changing climate conditions. Thus, long-term recommendations may include rating suitability of locations identified for planned investment in infrastructure, thereby allowing some locations to be selected over others according to a risk assessment based on global climate predictions. Alternatively, or in addition, long-term recommendations may include recommendations for infrastructure design, e.g., regarding foundations, drainage, elevations, and so on, according to a risk assessment based on global climate predictions. In at least some embodiments, the recommendations can be based on location details, planned usage, budgetary constraints, business strategies, and so on, presented in an easily understood and actionable manner.

In at least some embodiments, the recommendation process module 207 receives location details from a location detail source 208. The location detail source 208 may maintain and/or otherwise provide input data that defines one or more features, such as a property owner and/or operator, a function performed at and/or associated with the facility, e.g., identifying the location as residential, commercial, retail, a hospital. In at least some embodiments, the location detail source 208 may provide input data related to economic values, e.g., insured loss value, insured status, and so on. Other details may include, without limitation, demographic information, e.g., regarding residential applications, identification of sensitive equipment and/or elevations of any such equipment. Still other details may include specifications of maximum flood elevations.

In at least some embodiments, the recommendation process module 207 may receive input from a location history source 209. For example, the location history source 209 may maintain and/or otherwise have access to historical records related to the particular location and/or facility. The historical records can include information related to past flooding events. For example, if a facility as experienced a flood event, the historical information may include details related to preventative measures taken effectiveness of measures, actual flood depths versus earlier predictions, economic impact, facility modifications since a prior flood event, e.g., if preventive measures may have been taken to install additional drainage, pumps, flood hardening, and the like. It is understood that the recommendation process module 207 can be configured to provide recommendations according to data received from one or more of the risk assessment process module 206, the location detail source 208 and/or the location history source 209.

In at least some embodiments, the recommendation process module 207 is configured to determined recommendations according to predetermined and/or otherwise prescripted recommendations based on foreseeable combinations of the inputs. Alternatively, or in addition, the recommendation process module 207 can be configured to provide recommendations according to one or more rules and/or policies. For example, the recommendation process module 207 may be configured to provide recommendations based on a business logic as may be determined according to a business objective. Business objectives can be configured to consider economic impacts anticipated according to flood depths, e.g., tradeoffs comparing costs of preventive measures versus cost of reparative measures, allocation of limited resources across multiple different locations that may be impacted by one or more weather events, and so on.

The recommendation process module 207 can provide one or more recommendations 210, e.g., according to the illustrative examples provided herein. Without limitation, the recommendations can be provided in the form of a report, e.g., a periodic report as may be determined periodically according to a reporting schedule, e.g., daily, weekly, monthly, seasonally, annually and so on. Alternatively, or in addition, the recommendations may be initiated based on an event, such as a determination of a particular anticipated flood depth by the hydrologic evaluation process module 201, an estimated level of risk and/or risk label determined by the risk assessment module 206 and/or a recommendation as may be generated by the recommendation process module 207. In at least some embodiments, the recommendations 210 may include alarms, e.g., provided to a property owner and/or an operation and maintenance organization. The recommendation may include a text message, a phone call, an email, and/or some other prompt.

FIG. 2B is a block diagram illustrating an example, non-limiting embodiment of a flood-risk evaluation system 220 functioning within the communication system 100 of FIG. 1 in accordance with various aspects described herein. The example flood-risk evaluation system 220 includes a hydrological process module 223 receiving inputs from one or more of a climate data module 224, a weather model 225 and/or a terrain model 226. The hydrological process module 223 may be configure to determine a flood depth according to long term planning and/or according to a short-term event based on inputs from one or more of the climate data module 224, the weather model 225 and/or the terrain model 226. Long-term flood depths may provide a worst case anticipated pluvial flooding event over a future reporting period for a target location or region based on a projected climate condition. The climate data module 224 is configured to apply a projected climate condition to weather data, e.g., precipitation data, to obtain projections and/or forecasts according to an evaluation schedule, such that the projections and/or forecasted precipitate data takes into account a changing climate condition.

In at least some embodiments, short-term events based on inputs from one or more of the climate data module 224, the weather model 225 and/or the terrain model 226 can obtain weather forecast data, e.g., from the national weather service of a 7-day forecast, a 10-day forecast and/or a 14-day forecast. The climate data module 224 can provide an adjustment factor as may be applied to account for changing climate conditions. For example, the climate data module 224 may perform historical projections of weather data, e.g., precipitation data, for prior reporting periods with generally known climate conditions. In at least some embodiments, the climate data module 224 may be configured to apply current climate conditions to historical results to obtain a climate-adjusted estimates of historical records. For example, if the earlier projections determined according to actual historical climate conditions can be compared to repeat of earlier projections determined according to current climate conditions. The projections of the weather data, e.g., precipitation data, can be compared to determine a difference.

In some embodiments, the hydrological process module 223 can determine flood depth data for a target region based on the weather forecast from the weather model 225. The predicted flood depth data can be adjusted based on a factor determined according to a difference between historical records determined according to prior and current climate conditions.

The example flood-risk evaluation system 220 further includes one or more of a risk evaluation module 227 and a risk reporting module 228. The risk evaluation module 227 can be configured to receive flood depth data from the hydrologic process module 223 and to determine a corresponding risk data by applying a risk evaluation methodology, such as the examples disclosed herein. The risk reporting module 228 can be configured to generate and/or provide reports based on the risk evaluation data obtained from the risk evaluation module 227. The risk data can be reported according to a flood depth, a risk score, a risk label, a recommendation and/or any combination thereof.

In at least some embodiments, the flood-risk evaluation system 220 further includes a controller process module 222. The controller process module 222 can be in communication with one or more of the hydrologic process module 223, the risk evaluation module 227, the climate data module 224, the weather model 225 and/or the terrain model 226. The controller process module 222 can be configured to orchestrate control of one or more of the interconnected modules. Control can include, without limitation, initiating selection of a target region or location, selection of a climate condition, selection of terrain data associated with the target region. In at least some embodiments, control can include identification of a risk methodology, selection of a reporting period, a forecast period, and the like.

In at least some embodiments, the flood-risk evaluation system 220 further includes a user interface 221 (shown in phantom). The user interface can be used to affect a control process as may be implemented by the controller process module 222, e.g., making selections as may result in identification of a target location, a reporting period, a preference for long-term and/or short-term planning, and so on. According to the illustrative example, the user interface 221 is in communication with the controller process module 222 and the risk reporting module 228. For example, the user interface may include a textual, graphical and/or audio interface configured to provide textual data in the form of risk labels, alarms and/or recommendations. Alternatively, or in addition, the graphical interface may provide graphical representations of the target region, e.g., a map, with overlay data indicating one or more of flood depth data, flood risk data and/or flood risk label data. In at least some embodiments, the audible alarm may indicate receipt of a risk evaluation assessment, and/or that a risk assessment identifies a risk above some threshold, e.g., above 5 on a scale of 0-10, or recognition of a high risk occurring within the target region according to a low, medium high risk label.

FIG. 2C is a block diagram illustrating an example, non-limiting embodiment of a flood-risk evaluation system 230 functioning within the communication system 100 of FIG. 1 in accordance with various aspects described herein. The example flood-risk evaluation system 230 includes one or more global climate models 231 configured to provide climate-adjusted weather data according to one or more climate conditions. Weather data can include one or more weather indicators, such as temperature, e.g., average global temperature, wind speeds, changes in ocean currents, sea level rise, precipitation patterns, snowfall, ice sheet extent, cloud cover, humidity levels, extreme weather event frequency and so on. Models output data on a grid system, providing information for specific locations across the globe. Outputs can include mean values, e.g., average rainfall, variability, e.g., standard deviation of rainfall, and extreme events, e.g., frequency of heatwaves and/or periods of extreme rainfall. As the techniques disclosed herein relate to pluvial flooding events, weather indicators related to precipitation are of particular interest. Precipitation data may include precipitation amounts or totals over some reporting period, e.g., within one hour, or some number of hours and/or days as may be useful to determine total atmospheric contributions to surface water over some examination period and/or periods.

In at least some embodiments, the global climate model(s) 231 receives climate data 232 and/or global features 233. Climate data may include any of the various examples provided herein and/or otherwise known to those familiar with examining current and/or changing climate conditions. Global conditions can include conditions or factors, such as radiation, temperature, humidity, wind patterns, ocean currents, sea ice, land surface processes, urban development and so on.

In more detail, climate data can include, without limitation, current and/or historical climate conditions, e.g., actual and/or observed climate conditions. Alternatively, or in addition, climate data can include estimated and/or otherwise predicted or projected future climate conditions. Future climate conditions can be used to simulate climate-adjusted weather data under one or more different future climate conditions. Representative concentration pathways (RCPs) relate to climate change scenarios in which future greenhouse gas concentrations and/or other pollutants are used to evaluate the potential consequences of different climate change scenarios. There are multiple RCP scenarios, in which different greenhouse gas concentrations and radiative forcing are projected. For example, some RCP scenarios may represent a low emission scenario with limited climate change, other RPCs may represent other scenarios with moderate emissions expected to peak, while still other scenarios consider a high-emission scenario as may be experienced if efforts are not undertaken to curtail emissions. For example, a “business as usual” RCP scenario can be used to model potential consequences of insufficient action against climate change, such as increased reliance on fossil fuels and significant ecological challenges.

Examples of global climate models include: energy balance models (EBMs), which are the simplest type, intermediate complexity models (EMICs) that incorporate more geographical features like land and oceans, and general circulation models (GCMs), the most complex and precise models that simulate the full atmosphere-ocean system, often used to predict climate change with high detail; all of these models are considered “global climate models” and are used by scientists to study the Earth's climate system. Specific examples include, without limitation, the NCAR CESM (Community Earth System Model): Developed by the National Center for Atmospheric Research, GFDL CM (Geophysical Fluid Dynamics Laboratory Climate Model): Operated by NOAA's Geophysical Fluid Dynamics Laboratory, MPI-ESM (Max Planck Institute Earth System Model): Developed by the Max Planck Institute for Meteorology, or the IPSL (Institut Pierre Simon Laplace Climate Modelling Centre): A prominent European climate model. In at least some embodiments, the climate models include earth system models (ESMs) that incorporate complex interactions between two or more of the atmosphere, ocean, land surface, and/or carbon cycle. Examples include, without limitation, one or more of three prominent examples of global climate models in the Coupled Model Intercomparison Project 5 (CMIP5). More particularly, these models include the Community Climate System Model ver. 4(CCSM4 ), the Geophysical Fluid Dynamics Laboratory (GFDL) models, e.g., CM4, SPEAR, CM3, CM2.5 and FLOR, and the Hadley Centre Global Environmental Model (HadGEM) model. These example models represent good representation of the 40 global climate models in CMIP5.

Climate-adjusted weather data can be obtained according to a summary process, e.g., a precipitation summary, in which the precipitation data may be summarized according to certain conditions and/or time periods. For example, the precipitation may be summarized according to particular climate conditions, e.g., an RCP, and at various time periods, e.g., mid-century mean, end-of century mean, historical maximum, mid-century (2045-2054) maximum and/or end-of-century (2085-2094) maximum precipitations. In at least some embodiments, the summary results may be obtained according to particular time periods, e.g., particular months and/or seasons. In at least some embodiments, climate-adjusted weather data may be obtained from more than one global climate model and combined to obtain a combined result, e.g., according to a blend and/or average result. The results facilitate the examination of changes in intensity, duration, and frequency of precipitation, which, in turn, can be used to evaluate consequential flooding, e.g., pluvial flooding.

In at least some embodiments, outputs based on one or more of the global climate models 231, e.g., climate-adjusted weather data can be stored in a repository, such as the example coarse data set repository 234. The outputs based on the one or more of the global climate models 231, e.g., coarse climate-adjusted weather data sets from the coarse data set repository 234 may be provided as inputs to a regional climate model 235. In at least some embodiments, the regional climate model generates climate-adjusted weather data, e.g., precipitation data, according to a finer spatial resolution. For example, the regional climate model 235 can be configured to perform a dynamic downscaling of the coarse climate-adjusted weather datasets.

By way of example, the regional climate model 235 can apply one or more land surface models. Land surface models provide mathematical representations of physical and biogeochemical processes that occur at the Earth's surface and in the atmosphere, e.g., simulating an exchange of energy, water, momentum, and/or trace gases between the land and the atmosphere. It is understood that in at least some embodiments, the regional climate model 235 obtains regional feature data 236 as may be relevant in performing the dynamic downscaling operations. Regional features can include conditions or factors, such as radiation, temperature, humidity, wind patterns, ocean currents, sea ice, land surface processes, urban development and so on. In at least some embodiments, outputs based on one or more of the global climate models 231, e.g., climate-adjusted weather data can be stored in a repository, such as the example coarse data set repository 234. The regional climate model 235 provides outputs based on an application of one or more regional climate models, e.g., land surface models, to obtain refined climate-adjusted weather data sets, e.g., providing a finer spatial resolution than would otherwise be available from the coarse data sets. In at least some embodiments, the refined regional climate-adjusted weather data sets may be stored in a fine data set repository 237.

In at least some embodiments, the flood-risk evaluation system 230 includes a hydrologic model 238 configured to model terrestrial hydrologic processes related to the spatial redistribution of surface, subsurface and/or channel waters across the land surface and to facilitate coupling of hydrologic models with atmospheric models, e.g., the regional climate model 235 and/or the global climate models 231. At least one example of a hydrologic model is the WRF-Hydro® model, which provides a suite of terrestrial hydrologic routing physics modules; fully distributed, 3-dimensional, variably-saturated surface and subsurface flow model. The hydrologic model 238 can be configured to map land surface hydrological conditions from a ‘coarsely’ resolved land surface model grid to a much more finely resolved terrain routing grid capable of adequately resolving the dominant local landscape gradient features responsible for gravitational redistribution of terrestrial moisture. This provides a physics-based, fully coupled land surface hydrology-regional atmospheric modeling capability for use in hydrometeorological and hydro climatological research and applications. The output of the hydrologic model 238 can be provided as gridded input time series, as can be said for any of the various data disclosed herein, e.g., climate-adjusted atmospheric data, short-term weather forecast data, terrain data, risk evaluation data, risk scores, risk labels, and the like.

In at least some embodiments, the flood-risk evaluation system 230 includes a water model 239a and/or terrain data 240. The terrain data 240 can include any of the examples disclosed herein and/or otherwise generally known to those skilled in the art. The water model can include a hydrologic modeling framework that simulates observed and forecast streamflow, e.g., the National Water Model, which simulates a water cycle with mathematical representations of the different processes and how they fit together, e.g., snowmelt, infiltration and movement of water through soil layers as may vary significantly based on changing elevations, soils, vegetation, etc. Alternatively, or in addition, the flood-risk evaluation system 230 includes a short-term weather forecast model 239b, e.g., based on meteorological observational data and/or weather forecast models. Such forecasts can include, without limitation, precipitation forecasts, e.g., an 18-hour forecast, a 10-day forecast and/or a 30-day ensemble forecast. To the extent climate-adjusted data is considered, e.g., from the regional climate model 235 and/or the global climate models 232, the weather forecast may be adjusted according to a climate shift factor, e.g., based on differences in weather data projections under different climate conditions.

The hydrologic model 238 can be configured to provide flood depth data, e.g., according to a spatial grid and/or a spatio-temporal grid over the region of interest based on one or more of the aforementioned inputs. It is understood that the flood depth data may be applicable to long-term planning and/or for preparation and/readiness for short-term events, e.g., precipitation events as may be indicated by data provided by the weather forecast model 239b. In at least some embodiments, the hydrologic model 238 can take into consideration data from other sources 241, such as the FEMA National Flood Hazard Layer—available via web services (FEMA's GIS flood map services are available through FEMAs GeoPlatform, an ArcGIS Online portal containing a variety of FEMA-related data). This data may provide information indicating flood hazard zones, community boundaries and names, levees, hydraulic and flood control structures, etc. Such information may be used to enhance a confidence and/or to adjust predicted flood depth data. For example, flood depth data may be reduced to the extent hydraulic and flood control structures are identified.

In at least some embodiments, the flood-risk evaluation system 230 includes a risk evaluator and-or recommendation process module 242. The risk evaluator and or recommendation process module 242 can be configured to generate one or more risk reports, e.g., risk scores, risk labels and/or recommendations, which may be provided in the form of reports 248 and/or user accessible datasets. According to the illustrative example, the risk evaluator and/or recommendation process module 242 includes a scoring module 243. The scoring module 243 is configured to receive an input from the hydrologic model 238, e.g., in the form of flood depth data. As indicated, this may include flood depth data according to a spatial grid and/or a spatio-temporal grid. The scoring module 243 can be configured to apply a scoring methodology and/or a classification to obtain flood risk score data based on the flood depth data. The scoring process can include any of the various examples disclosed herein and/or otherwise generally known. Once again, the flood risk score data may be provided according to a spatial grid and/or a spatio-temporal grid.

In at least some embodiments, the risk evaluator and/or recommendation process module 242 includes a labeling module 244. The labeling module 244 is configured to receive an input from the scoring module 243 and to apply a labeling methodology and/or a classification to obtain flood risk label data. The labeling process can include any of the various examples disclosed herein and/or otherwise generally known. Once again, the flood risk label data may be provided according to a spatial grid and/or a spatio-temporal grid. It is worth noting here that at any point in the example processes disclosed herein, it is understood that data provided according to one grid system may be translated and/or otherwise transformed into another grid system.

In at least some embodiments the risk evaluator and/or recommendation process module 242 may apply one or more rules, e.g., business rules 246 to one or more of the scoring process and/or the labeling process. Example business rules 246 (shown in phantom) may be provided as inputs to one or more of the scoring module 243 and/or the labeling module 244. It is envisioned that, in at least some embodiments, the scoring module 243 may receive supporting information, e.g., in the form of other factors 245a (shown in phantom) as may be useful in applying a scoring methodology. Likewise, in at least some embodiments, the labeling module 244 may receive supporting information, e.g., in the form of other factors 245b (also shown in phantom) as may be useful in applying a labeling methodology.

In at least some embodiments the risk evaluator and/or recommendation process module 242 may apply historical observations, e.g., according to historical records 247, to one or more of the scoring process and/or the labeling process. It is further envisioned that artificial intelligence (AI) and/or machine learning (ML) may be applied to any of the various procedure, processes and/or techniques disclosed herein. For example, the risk evaluator and/or recommendation process module 242 may include an AI/ML module 249 configured to apply an AI model to one or more of the scoring and/or labeling processes. To this end, the AI/ML module may receive input data from the historical records to perform a training process in which previously generated scoring and/or labeling data may be used. Namely, the AI/ML model may be allowed to generate a result, e.g., a score and/or a label based on input data, such as flood depth data, location data, facility data, flood risk score data and the like.

According to a training process, predictions generated by the AI/ML module 249 may be compared against actual observations, resulting in an error value which may be provided to the AI/ML module 249 in accordance with the training process. The AI/ML module 249, e.g., a neural network, such as a deep neural network including hidden nodes, may make adjustments to model values to obtain an updated prediction, which, in turn, may be compared again to obtain an updated error, until the error has fallen below some suitable threshold, in which instance the model can be said to be suitably trained. The trained model may be leveraged by one or more of the scoring module 243 and the labeling module 244 to obtain AI/ML predicted results.

FIG. 2D is a flood depth map 250 illustrating an example, non-limiting embodiment of dynamically downscaled flood-depth input data to a flood-risk evaluation system of FIGS. 2A, 2B, 2C, functioning within the communication system of FIG. 1 in accordance with various aspects described herein. The flood depth map 250 illustrates a graphical representation of a location or region of interest, e.g., a target region. The flood depth map 250 can include indications of terrain features, such as lakes rivers, roads, forest, urban development, and the like. In at least some embodiments, the flood depth map 250 includes a flood depth data layer that provides flood-depth determination points 251, e.g., circles, at locations on the flood depth map 250 at which flood depth data was determined.

According to the illustrative example, the flood depth map 250 can be provided in an interactive format in which a user can select one or more of the flood-depth determination points 251 to access detailed flood depth data. According to the illustrative embodiment, the detailed flood depth data can be provided in a detail window 252. The detail window 252 may be presented as a splash screen and information box, presenting information such as a location of the flood-depth determination point 251, e.g., a latitude and longitude. Other details may include a flood depth in inches accompanied by any other qualifying details, such as whether the flood depth is a historical record, and/or a projection or forecast.

FIG. 2E is a risk label map 255 diagram illustrating an example, non-limiting embodiment of a flood risk map determined by a flood-risk evaluation system of FIGS. 2A, 2B, 2C, based on the dynamically downscaled flood-depth input data, in accordance with various aspects described herein. The risk label map 255 illustrates a graphical representation of a location or region of interest, e.g., the same target region illustrated in the flood depth map 250 (FIG. 2D). The risk label map 255 can include indications of terrain features, such as lakes rivers, roads, forest, urban development, and the like. In at least some embodiments, the risk label map 255 includes a risk score and/or risk label data layer that provides a risk score and/or risk label at various locations across the risk label map 255. In at least some embodiments, the risk score and/or risk label data may be determined according to the flood depth data, e.g., at the risk assessment location or risk assessment point 256. However, the risk sores and/or labels may be presented according to a more regular grid, e.g., at regular cells, polygons, distributed across the risk label map 255, possibly covering an entire region portrayed in the risk label map 255.

According to the illustrative example, the risk label map 255 also can be provided in an interactive format in which a user can select one or more of the flood-depth determination polygons, e.g., rectangles or squares of the risk assessment point 256 256 to access detailed flood depth data and/or risk score and/or risk label data. According to the illustrative embodiment, the detailed flood depth data can be provided in a detail window 258. The detail window 258 may be presented as a splash screen and information box, presenting information such as a location of the risk assessment point 256, e.g., a latitude and longitude. Other details may include a flood depth in inches accompanied by any other qualifying details, such as whether the flood depth is a historical record, and/or a projection or forecast. In at least some embodiments, the risk label map 255 includes a legend 257 identifying different risk scores and/or risk labels as portrayed in the risk label map 255. According to the illustrative example, the risk labels are portrayed as shading and/or color at a resolution of the risk assessment point 256. The legend 257 can associate the shading and/or color values according to a corresponding risk score and/or risk label. Accordingly, the risk assessment may be easily interpreted according to the shading and/or color scale without requiring any special knowledge of the implications of particular flood depth values and/or ranges. It is understood that a presentation of the risk scores and/or risk labels according to the risk label map 255 can be interpreted as actionable results. For example, a facility owner and/or operator presented with the results of the risk label map 255 may identify any risks related to pluvial flood depths at facility locations within the region of interest. The owner/operator may be provided with an action list based on a feature of the facility, e.g., a related function, associated economic value or risk, historical details related to the facility, and the like.

FIG. 2F depicts an illustrative embodiment of a flood-risk evaluation process 260 in accordance with various aspects described herein. The example flood-risk evaluation process 260 includes determining a region of interest at 261. The region of interest can include a geographic region including one or more facilities and/or locations of interest. For example, a wireless network operator may identify a region of interest as a region containing a location of a cell tower.

The example flood-risk evaluation process 260 further includes generating dynamically downscaled climate data at 262. The climate data can include, without limitation, weather data obtained according to a climate state determined according to a changing climate condition. The climate data can include weather data, such as precipitation data. In at least some embodiments, the climate data is obtained from a model adapted to determine climate-adjusted weather data, e.g., precipitation according to a relatively large region. Accordingly, the climate-adjusted weather data is computed according to a relatively coarse resolution over a relatively large area, e.g., nationally and/or globally. The coarseness may be on the order of several kilometers and generally too large to prove useful for identifying flood depth estimates based on a facility that may include a location determined according to sub-kilometer resolution, e.g., tens to hundreds of meters. In at least some embodiments, the climate-adjusted weather data determined at a coarse resolution may be dynamically downscaled to a finer resolution over a relatively small area. The dynamically downscaling may use the relatively coarse climate-adjusted data as a boundary condition and/or forcing function for an application of the climate-adjusted weather model to re-interpret climate-adjusted weather data according to the finer scale, e.g., at tens and/or hundreds of meters.

According to the example flood-risk evaluation process 260, climate data is applied to a hydrological process model at 263. The hydrological process model can apply physics models according to physical processes that relate to water flow along a terrain surface. Contributing factors may include elevation data as may be determined according to a topological model of the region of interest. Alternatively, or in addition, the contributing factors may include soil composition and/or soil moisture content and/or ground water state.

According to the example flood-risk evaluation process 260, terrain flood depth data is generated based on results obtained from application of the hydrological process model at 264. The precipitation data obtained from the climate-adjusted weather data can be applied in the modeled physical processes of the hydrological process model to obtain inundation depth data over the region of interest.

According to the example flood-risk evaluation process 260, terrain flood depth data is translated to a grid at 265. It is understood that the flood depths may be determined according to a first spatial arrangement, e.g., a first grid or pattern, which may or may not align with any particular grid. It is understood that the flood depth data can be translated and/or otherwise transferred and/or interpolated to data that aligns with a second grid structure. In at least some embodiments, the terrain flood depth data according to the first spatial arrangement is effectively overlaid with the second grid and values of the second grid can be determined based on a number and/or value of flood depth data points that may fall within a resolution zone, e.g., a polygon of the second grid.

According to the example flood-risk evaluation process 260, flood depth risk data is generated at 266. It is envisioned that a flood risk evaluation methodology can be applied to the flood depth data in order to translate it and/or otherwise classify the flood depth data according to a risk score.

According to the example flood-risk evaluation process 260, the flood depth risk data is associated with a flood depth label at 267. It is envisioned further that a flood depth and/or flood risk data, e.g., a flood risk score as may have been determined at 266, can be translated to a label. The label may be textual, numerical, graphical, e.g., related to a shading and/or color, and perhaps audible.

FIG. 2G depicts another illustrative embodiment of a flood-risk evaluation process 270 in accordance with various aspects described herein. The flood-risk evaluation process 270 includes determining dynamically downscaled climate data at 271a. The dynamically downscaled climate data can include dynamically downscaled climate-adjusted weather data, e.g., precipitation data, determined according to a changing climate state.

The flood-risk evaluation process 270 further includes determining a weather forecast at 271b. It is understood that the flood-risk evaluation process 270 may include long-term projections or forecasts, e.g., to obtain estimates of daily averages, seasonal averages, yearly averages and/or averages determined according to longer time periods. Alternatively, or in addition the long-term projections or forecasts can be adapted to estimate worst case precipitation events over any or all of the example time periods. Such long-term climate-adjusted data can be useful in long-term planning, such as long-term planning for infrastructure of the example mobile telecommunication network. Consider locations for network build outs being selected and/or environmental hardening of existing facilities being applied based on climate-adjusted weather data to take into consideration variations as may be expected due to changing climate conditions.

It is understood further that in at least some embodiments, the flood-risk evaluation process 270 may include short-term projections or forecasts, e.g., to obtain forecasts over the very near term, e.g., hours, days and/or weeks as may be useful to identify risks associated with immediate weather events. According to the illustrative climate-adjusted weather forecasting techniques disclosed herein, it is understood that short-term projections or forecasts can be adapted in view of the climate-adjusted weather data. For example, climate-adjusted weather forecasts for a region of interest may be obtained at different time periods, e.g., historical and/or in the future, to obtain a measure of a trend and or amount of a change in predicted weather data as may be attributable to variations in the climate state as accounted for in the models. Such trends can be used to adjust short-term forecasts and/or risk evaluations based on the short-term forecasts.

Accordingly, the climate-adjusted weather data can be useful in short-term planning, such as short-term planning for protecting infrastructure of the example mobile telecommunication network. Short-term flood risks based on climate-adjusted weather data can be used to identify risks and/or to provide recommendations for protecting and/or otherwise securing existing facilities in view of a near-term weather event, such as a storm being tracked in the short-term forecasts. A tropical storm or hurricane provides an example in which forecasts may vary in severity based on changing climate data.

Local terrain data can be obtained at 271c. Local terrain data can include topographical data including elevation data. Alternatively, or in addition the location terrain data can include other information, such as soil type, land-use, ground water content, and so on.

According to the example flood-risk evaluation process 270, climate data determined at 271a is applied to the hydrologic process model at 272. In at least some embodiments, one or more of the weather forecast obtained at 271b and/or the local terrain data obtained at 271c are also applied to the hydrologic process model at 272. This can include application of long-term flood depth data and/or short-term flood depth data determined as may be determined from climate-adjusted weather data as discussed above.

According to the example flood-risk evaluation process 270, flood depth data, e.g., in the form of a flood depth report, is generated at 273. The flood depth report may include flood depth data as determined according to an application of the hydrological model at 272. In at least some embodiments, a business application is determined at 274. According to the example flood-risk evaluation process 270, risk-related rules can be identified at 275, e.g., based upon the determined business application. Risk related rules, e.g., as determined at 275, can be applied at 276, e.g., to generate flood depth risk data at 277. A business application may include a type of facility, an occupant and/or tenant at the facility and/or a function related to the facility. The current examples include mobile network operator facilities, such as radio towers, equipment cabinets, buried fiber, line-of-sight optical and/or microwave links, powerline communications, data centers, and so on. In at least some embodiments, historical context (shown in phantom) can be determined at 279 and considered in the generation of the flood depth risk data at 277. Historical context can include experiences at the facility during prior flood event. Experiences can include, without limitation, environmental hardening efforts applied, their effectiveness, damage suffered, and the like.

According to the example flood-risk evaluation process 270, the flood depth risk label can be generated at 278. For example, the flood depth risk label can be determined according to the flood depth risk data generated at 277 and, in at least some embodiments, in view of the business application determined at 274. It is envisioned that such flood risk labels can be much more easily interpreted by facility planners and/or maintenance and operation crews.

FIG. 2H depicts yet another illustrative embodiment of a flood-risk evaluation process 280 in accordance with various aspects described herein. The example flood-risk evaluation process 280 includes determining long-term climate-adjusted weather data at 281a, wherein long term indicates months or years. According to the example flood-risk evaluation process 280, near term weather data is determined at 281b, wherein near term indicates hours or days, but generally not more than about two weeks. Further according to the example flood-risk evaluation process 280, local terrain data is obtained at 281c. Terrain data can include ground conditions, such as elevation data.

Flood depth projections are determined at 282, e.g., as inundation depts as may be measured in inches and/or feet and converted to risk metrics at 283. Risk metrics can include a risk score, e.g., determined from a conversion of flood depth to a numeric value according to a scoring range. One or more locations are identified at 284. The locations can include a region, e.g., determined according to a range of geocoordinates, terrain features and/or geopolitical borders. Alternatively, or in addition, the locations may be identified according to addresses and/or other references, such as a names of a facilities, owners and/or operators, functions performed at or by the facilities, and or any combination thereof capable of unambiguously identifying the locations.

According to the example flood risk evaluation process 280, risk evaluations are performed at 285. The flood risk evaluations can be performed at one or more regions or locations, including the locations identified at 284. For example, a business, such as a mobile network operator, may operate multiple facilities within a region, e.g., a county, city, town or state. The facilities may be related to the business of operating the mobile network. Accordingly, the locations may include the multiple facilities of the mobile network operator, such that the flood risk evaluations are performed over the region encompassing the locations of the mobile network operator facilities. It is envisioned that in at least some embodiments, the location can be adjusted, e.g., via user interface and/or other instructions, e.g., to establish a range, perhaps a maximum range of a region as might limit locations to those occurring within the maximum range, e.g., within a 100-mile range or a 10-mile range, or within a particular state, county, city and/or town.

A determination is made at 286 as to whether an action plan is required. In at least some embodiments, the determination can be based at least in part upon the risk metrics. For example, one or more thresholds may be established, such that an action plane is required when risk scores exceed the threshold(s) at and/or near the locations of interest, while an action plan may not be required if all risk scores do not exceed the threshold(s). It is understood that a logic may be applied to this determination based on any one or more factors, such as maximum risk metrics anywhere within the region of interest, and/or maximum risk metrics occurring at and/or near particular locations, such as the facilities of the mobile network operator. Alternatively, or in addition, the action plan may be based on a temporal aspect, such as a duration of the risk metrics, e.g., that risk metrics are reported above some threshold value for some period of time. In at least some embodiments, the logic, e.g., the thresholds, ranges and/or time durations may be selectable, e.g., via a user interface. Alternatively, or in addition, the logic can depend upon other factors, such as an identity of the owner/operator of the facilities, functions associated with the facilities and so on.

To the extent it is determined at 286 that an action plan is required, an action plan is generated at 287. In at least some embodiments, the action plan can provide general recommendations, e.g., prepare for possible low-level, or severe inundations as may result from a near-term weather event. Alternatively, or in addition, the action plan provides more specific details, e.g., recommended actions, such as divert operations performed at the facility to another location, terminate electrical power, perform sandbagging, inspect readiness of flood-prevention equipment, e.g., pumps, drains, backup power and so on. In at least some embodiments, the recommendations may relate to long-term planning events. For example, the recommendations may recommend an addition of and/or enhancement of flood-prevention equipment. It is understood that in at least some embodiments, the action plan may include a time element, e.g., a particular time and/or number of hours and/or days within which the action plan should be enacted upon for short-term weather events and/or a number of months, years or decades within which the action plan should be enacted upon for long-term weather trends.

To the extent it is determined at 286 that an action plan is not required, a further determination is made at 288 as to whether updated risk evaluations are required. To the extent it is determined at 288 that updated risk evaluations are required, the process returns to determine updated flood depth projections at 282, e.g., based on inputs from one or more of the long term climate data determined at 281a, the near-term weather data determined at 281b and/or the local terrain data obtained at 281c.

While for purposes of simplicity of explanation, the respective processes are shown and described as a series of blocks in FIGS. 2F, 2G, 2H and 2I, it is to be understood and appreciated that the claimed subject matter is not limited by the order of the blocks, as some blocks may occur in different orders and/or concurrently with other blocks from what is depicted and described herein. Moreover, not all illustrated blocks may be required to implement the methods described herein.

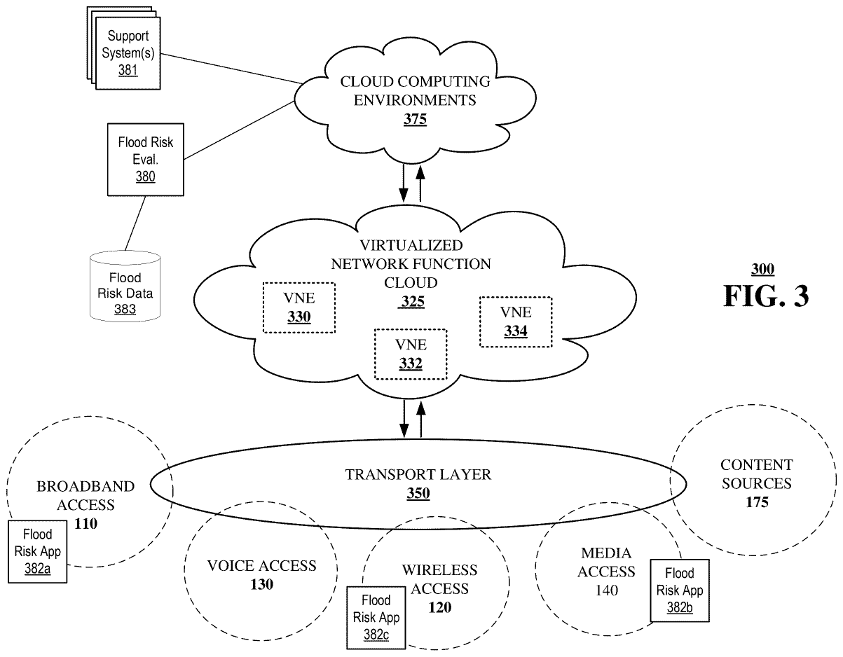

Referring now to FIG. 3, a block diagram is shown illustrating an example, non-limiting embodiment of a virtualized communication network 300 in accordance with various aspects described herein. In particular a virtualized communication network 300 is presented that can be used to implement some or all of the subsystems and functions of system 100, the subsystems and functions of systems 200, 220, 230, and processes 26, 270, 280 presented in FIGS. 1, 2A, 2B, 2C, 2D, 2E, 2F, 2G, 2H and 3. For example, virtualized communication network 300 can facilitate in whole or in part determining climate-compensated precipitation data, estimating inland flood depths of a region based on the precipitation data and local terrain data, and classifying the inland flood depths according to risk scores to obtain a risk score map of the region. The risk scores and/or labels based on the risk scores can be shared with facility planning and/or maintenance organizations to inform them of pluvial flood risks associated with changing climate conditions. The classified risk scores and/or labels are easily interpretable to inform planners of short and/or long-term events.

In particular, a cloud networking architecture is shown that leverages cloud technologies and supports rapid innovation and scalability via a transport layer 350, a virtualized network function cloud 325 and/or one or more cloud computing environments 375. In various embodiments, this cloud networking architecture is an open architecture that leverages application programming interfaces (APIs); reduces complexity from services and operations; supports more nimble business models; and rapidly and seamlessly scales to meet evolving customer requirements including traffic growth, diversity of traffic types, and diversity of performance and reliability expectations.

In contrast to traditional network elements—which are typically integrated to perform a single function, the virtualized communication network 300 employs virtual network elements (VNEs) 330, 332, 334, etc., that perform some or all of the functions of network elements 150, 152, 154, 156, etc. For example, the network architecture can provide a substrate of networking capability, often called Network Function Virtualization Infrastructure (NFVI) or simply infrastructure that is capable of being directed with software and Software Defined Networking (SDN) protocols to perform a broad variety of network functions and services. This infrastructure can include several types of substrates. The most typical type of substrate being servers that support Network Function Virtualization (NFV), followed by packet forwarding capabilities based on generic computing resources, with specialized network technologies brought to bear when general-purpose processors or general-purpose integrated circuit devices offered by merchants (referred to herein as merchant silicon) are not appropriate. In this case, communication services can be implemented as cloud-centric workloads.

As an example, a traditional network element 150 (shown in FIG. 1), such as an edge router can be implemented via a VNE 330 composed of NFV software modules, merchant silicon, and associated controllers. The software can be written so that increasing workload consumes incremental resources from a common resource pool, and moreover so that it is elastic: so, the resources are only consumed when needed. In a similar fashion, other network elements such as other routers, switches, edge caches, and middle boxes are instantiated from the common resource pool. Such sharing of infrastructure across a broad set of uses makes planning and growing infrastructure easier to manage.

In an embodiment, the transport layer 350 includes fiber, cable, wired and/or wireless transport elements, network elements and interfaces to provide broadband access 110, wireless access 120, voice access 130, media access 140 and/or access to content sources 175 for distribution of content to any or all of the access technologies. In particular, in some cases a network element needs to be positioned at a specific place, and this allows for less sharing of common infrastructure. At other times, the network elements have specific physical layer adapters that cannot be abstracted or virtualized and might require special DSP code and analog front ends (AFEs) that do not lend themselves to implementation as VNEs 330, 332 or 334. These network elements can be included in transport layer 350.

The virtualized network function cloud 325 interfaces with the transport layer 350 to provide the VNEs 330, 332, 334, etc., to provide specific NFVs. In particular, the virtualized network function cloud 325 leverages cloud operations, applications, and architectures to support networking workloads. The virtualized network elements 330, 332 and 334 can employ network function software that provides either a one-for-one mapping of traditional network element function or alternately some combination of network functions designed for cloud computing. For example, VNEs 330, 332 and 334 can include route reflectors, domain name system (DNS) servers, and dynamic host configuration protocol (DHCP) servers, system architecture evolution (SAE) and/or mobility management entity (MME) gateways, broadband network gateways, IP edge routers for IP-VPN, Ethernet and other services, load balancers, distributers and other network elements. Because these elements do not typically need to forward large amounts of traffic, their workload can be distributed across a number of servers—each of which adds a portion of the capability, and which creates an elastic function with higher availability overall than its former monolithic version. These virtual network elements 330, 332, 334, etc., can be instantiated and managed using an orchestration approach similar to those used in cloud compute services.

The cloud computing environments 375 can interface with the virtualized network function cloud 325 via APIs that expose functional capabilities of the VNEs 330, 332, 334, etc., to provide the flexible and expanded capabilities to the virtualized network function cloud 325. In particular, network workloads may have applications distributed across the virtualized network function cloud 325 and cloud computing environment 375 and in the commercial cloud or might simply orchestrate workloads supported entirely in NFV infrastructure from these third-party locations.

According to the illustrative embodiment, the virtualized communication network 300 includes and/or otherwise supports operation of a flood risk evaluation system 380 configured to estimate inland flood depths of a region based on climate-compensated precipitation data, in view of local terrain data, and to classify the flood depths according to risk scores to obtain a risk score map of the region. To the extent the flood risk evaluation system 380 relies upon one or more supporting systems 381, such as database systems and/or models, the supporting systems 381 may be accessible via the virtualized network function cloud 325. Alternatively, or in addition, at least some of the supporting systems 381 may be incorporated into the flood risk evaluation system 380 and/or otherwise locally accessible.

In at least some embodiments, the virtualized communication network 300 further includes a data store 383 that may include a data storage system or device, e.g., a network drive and/or a database. At least a portion of the data store 383, when utilized, may be provided locally to the flood risk evaluation system 380. Alternatively, or in addition, at least a portion of the data store 383 may be remote from the flood risk evaluation system 380, e.g., accessible via the virtualized network function cloud 325.

It is envisioned that reporting information produced by the flood risk evaluation system 180 may be distributed, posted and/or otherwise made available to consumers of the various reporting content. To this end, the flood risk evaluation system 380 may include a web-accessible portal as may be accessed from one or more end user systems and/or devices via respective access networks, e.g., the example broadband access network 110, the wireless access network 120 and/or the media access network 140. Alternatively, or in addition, end user devices and/or systems may host one or more application programs 382a, 382b, 382c, generally 382, as may be distributed and/or otherwise made available via one or more of the example broadband access network 110, the wireless access network 120 and/or the media access network 140, to facilitate access to reporting information produced by the flood risk evaluation system 380. Alternatively, or in addition, one or more of such web portals and/or application programs 382 can include a user interface configured to enable interaction with one or more of the flood risk evaluation system 380, the data store 383 and/or the supporting systems 381.

It is envisioned that one or more of the flood risk evaluation system 380, the data store 383 and/or the supporting systems 381 may be embodied in respective system components that may be localized and/or distributed and/or otherwise accessible via the virtualized communication network 325. Alternatively, or in addition, it is understood that a portion or all of any one or more of the flood risk evaluation system 380, the data store 383 and/or the supporting systems 381 may be incorporated into the communication network 325, e.g., in one or more of the example VNEs 352. In at least some embodiments, any portion and/or all of any one or more of the flood risk evaluation system 380, the data store 383 and/or the supporting systems 381 may be virtualized, e.g., provided at least partly within the example cloud computing environments 375.

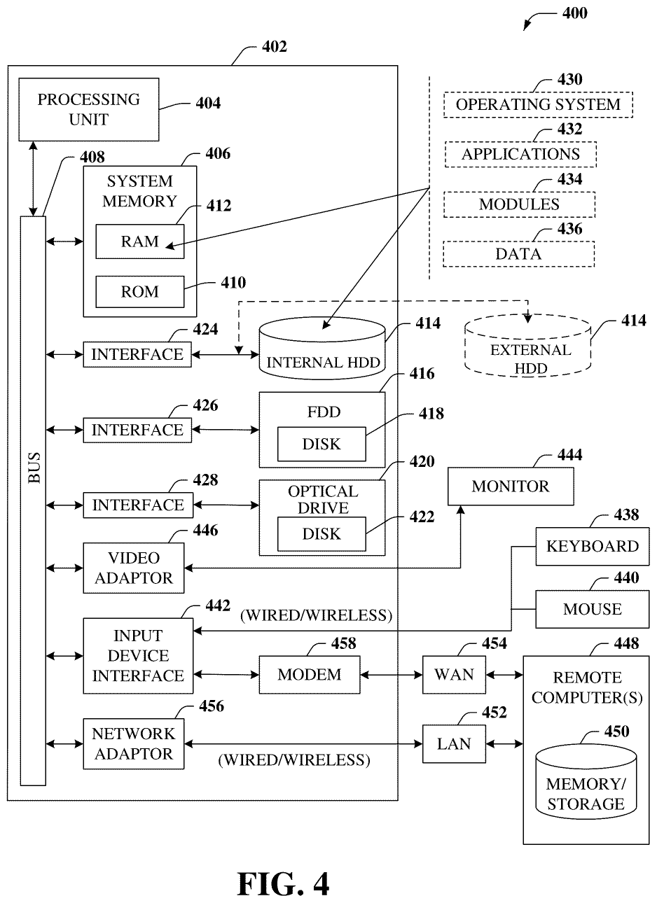

Turning now to FIG. 4, there is illustrated a block diagram of a computing environment 400 in accordance with various aspects described herein. In order to provide additional context for various embodiments of the embodiments described herein, FIG. 4 and the following discussion are intended to provide a brief, general description of a suitable computing environment 400 in which the various embodiments of the subject disclosure can be implemented. In particular, computing environment 400 can be used in the implementation of network elements 150, 152, 154, 156, access terminal 112, base station or access point 122, switching device 132, media terminal 142, and/or VNEs 330, 332, 334, etc. Each of these devices can be implemented via computer-executable instructions that can run on one or more computers, and/or in combination with other program modules and/or as a combination of hardware and software. For example, computing environment 400 can facilitate in whole or in part determining climate-compensated precipitation data, estimating inland flood depths of a region based on the precipitation data and local terrain data, and classifying the inland flood depths according to risk scores to obtain a risk score map of the region. The risk scores and/or labels based on the risk scores can be shared with facility planning and/or maintenance organizations to inform them of pluvial flood risks associated with changing climate conditions. The classified risk scores and/or labels are easily interpretable to inform planners of short and/or long-term events.

Generally, program modules comprise routines, programs, components, data structures, etc., that perform particular tasks or implement particular abstract data types. Moreover, those skilled in the art will appreciate that the methods can be practiced with other computer system configurations, comprising single-processor or multiprocessor computer systems, minicomputers, mainframe computers, as well as personal computers, hand-held computing devices, microprocessor-based or programmable consumer electronics, and the like, each of which can be operatively coupled to one or more associated devices.

As used herein, a processing circuit includes one or more processors as well as other application specific circuits such as an application specific integrated circuit, digital logic circuit, state machine, programmable gate array or other circuit that processes input signals or data and that produces output signals or data in response thereto. It should be noted that any functions and features described herein in association with the operation of a processor could likewise be performed by a processing circuit.

The illustrated embodiments of the embodiments herein can be also practiced in distributed computing environments where certain tasks are performed by remote processing devices that are linked through a communications network. In a distributed computing environment, program modules can be located in both local and remote memory storage devices.

Computing devices typically comprise a variety of media, which can comprise computer-readable storage media and/or communications media, which two terms are used herein differently from one another as follows. Computer-readable storage media can be any available storage media that can be accessed by the computer and comprises both volatile and nonvolatile media, removable and non-removable media. By way of example, and not limitation, computer-readable storage media can be implemented in connection with any method or technology for storage of information such as computer-readable instructions, program modules, structured data or unstructured data.

Computer-readable storage media can comprise, but are not limited to, random access memory (RAM), read only memory (ROM), electrically erasable programmable read only memory (EEPROM), flash memory or other memory technology, compact disk read only memory (CD-ROM), digital versatile disk (DVD) or other optical disk storage, magnetic cassettes, magnetic tape, magnetic disk storage or other magnetic storage devices or other tangible and/or non-transitory media which can be used to store desired information. In this regard, the terms “tangible” or “non-transitory” herein as applied to storage, memory or computer-readable media, are to be understood to exclude only propagating transitory signals per se as modifiers and do not relinquish rights to all standard storage, memory or computer-readable media that are not only propagating transitory signals per se.

Computer-readable storage media can be accessed by one or more local or remote computing devices, e.g., via access requests, queries or other data retrieval protocols, for a variety of operations with respect to the information stored by the medium.

Communications media typically embody computer-readable instructions, data structures, program modules or other structured or unstructured data in a data signal such as a modulated data signal, e.g., a carrier wave or other transport mechanism, and comprises any information delivery or transport media. The term “modulated data signal” or signals refers to a signal that has one or more of its characteristics set or changed in such a manner as to encode information in one or more signals. By way of example, and not limitation, communication media comprise wired media, such as a wired network or direct-wired connection, and wireless media such as acoustic, RF, infrared and other wireless media.

With reference again to FIG. 4, the example environment can comprise a computer 402, the computer 402 comprising a processing unit 404, a system memory 406 and a system bus 408. The system bus 408 couples system components including, but not limited to, the system memory 406 to the processing unit 404. The processing unit 404 can be any of various commercially available processors. Dual microprocessors and other multiprocessor architectures can also be employed as the processing unit 404.

The system bus 408 can be any of several types of bus structure that can further interconnect to a memory bus (with or without a memory controller), a peripheral bus, and a local bus using any of a variety of commercially available bus architectures. The system memory 406 comprises ROM 410 and RAM 412. A basic input/output system (BIOS) can be stored in a non-volatile memory such as ROM, erasable programmable read only memory (EPROM), EEPROM, which BIOS contains the basic routines that help to transfer information between elements within the computer 402, such as during startup. The RAM 412 can also comprise a high-speed RAM such as static RAM for caching data.

The computer 402 further comprises an internal hard disk drive (HDD) 414 (e.g., EIDE, SATA), which internal HDD 414 can also be configured for external use in a suitable chassis (not shown), a magnetic floppy disk drive (FDD) 416, (e.g., to read from or write to a removable diskette 418) and an optical disk drive 420, (e.g., reading a CD-ROM disk 422 or, to read from or write to other high-capacity optical media such as the DVD). The HDD 414, magnetic FDD 416 and optical disk drive 420 can be connected to the system bus 408 by a hard disk drive interface 424, a magnetic disk drive interface 426 and an optical drive interface 428, respectively. The hard disk drive interface 424 for external drive implementations comprises at least one or both of Universal Serial Bus (USB) and Institute of Electrical and Electronics Engineers (IEEE) 1394 interface technologies. Other external drive connection technologies are within contemplation of the embodiments described herein.

The drives and their associated computer-readable storage media provide nonvolatile storage of data, data structures, computer-executable instructions, and so forth. For the computer 402, the drives and storage media accommodate the storage of any data in a suitable digital format. Although the description of computer-readable storage media above refers to a hard disk drive (HDD), a removable magnetic diskette, and a removable optical media such as a CD or DVD, it should be appreciated by those skilled in the art that other types of storage media which are readable by a computer, such as zip drives, magnetic cassettes, flash memory cards, cartridges, and the like, can also be used in the example operating environment, and further, that any such storage media can contain computer-executable instructions for performing the methods described herein.

A number of program modules can be stored in the drives and RAM 412, comprising an operating system 430, one or more application programs 432, other program modules 434 and program data 436. All or portions of the operating system, applications, modules, and/or data can also be cached in the RAM 412. The systems and methods described herein can be implemented utilizing various commercially available operating systems or combinations of operating systems.

A user can enter commands and information into the computer 402 through one or more wired/wireless input devices, e.g., a keyboard 438 and a pointing device, such as a mouse 440. Other input devices (not shown) can comprise a microphone, an infrared (IR) remote control, a joystick, a game pad, a stylus pen, touch screen or the like. These and other input devices are often connected to the processing unit 404 through an input device interface 442 that can be coupled to the system bus 408, but can be connected by other interfaces, such as a parallel port, an IEEE 1394 serial port, a game port, a universal serial bus (USB) port, an IR interface, etc.

A monitor 444 or other type of display device can be also connected to the system bus 408 via an interface, such as a video adapter 446. It will also be appreciated that in alternative embodiments, a monitor 444 can also be any display device (e.g., another computer having a display, a smart phone, a tablet computer, etc.) for receiving display information associated with computer 402 via any communication means, including via the Internet and cloud-based networks. In addition to the monitor 444, a computer typically comprises other peripheral output devices (not shown), such as speakers, printers, etc.

The computer 402 can operate in a networked environment using logical connections via wired and/or wireless communications to one or more remote computers, such as a remote computer(s) 448. The remote computer(s) 448 can be a workstation, a server computer, a router, a personal computer, portable computer, microprocessor-based entertainment appliance, a peer device or other common network node, and typically comprises many or all of the elements described relative to the computer 402, although, for purposes of brevity, only a remote memory/storage device 450 is illustrated. The logical connections depicted comprise wired/wireless connectivity to a local area network (LAN) 452 and/or larger networks, e.g., a wide area network (WAN) 454. Such LAN and WAN networking environments are commonplace in offices and companies, and facilitate enterprise-wide computer networks, such as intranets, all of which can connect to a global communications network, e.g., the Internet.

When used in a LAN networking environment, the computer 402 can be connected to the LAN 452 through a wired and/or wireless communication network interface or adapter 456. The adapter 456 can facilitate wired or wireless communication to the LAN 452, which can also comprise a wireless AP disposed thereon for communicating with the adapter 456.

When used in a WAN networking environment, the computer 402 can comprise a modem 458 or can be connected to a communications server on the WAN 454 or has other means for establishing communications over the WAN 454, such as by way of the Internet. The modem 458, which can be internal or external and a wired or wireless device, can be connected to the system bus 408 via the input device interface 442. In a networked environment, program modules depicted relative to the computer 402 or portions thereof can be stored in the remote memory/storage device 450. It will be appreciated that the network connections shown are examples and other means of establishing a communications link between the computers can be used.

The computer 402 can be operable to communicate with any wireless devices or entities operatively disposed in wireless communication, e.g., a printer, scanner, desktop and/or portable computer, portable data assistant, communications satellite, any piece of equipment or location associated with a wirelessly detectable tag (e.g., a kiosk, news stand, restroom), and telephone. This can comprise Wireless Fidelity (Wi-Fi) and BLUETOOTH® wireless technologies. Thus, the communication can be a predefined structure as with a conventional network or simply an ad hoc communication between at least two devices.

Wi-Fi can allow connection to the Internet from a couch at home, a bed in a hotel room or a conference room at work, without wires. Wi-Fi is a wireless technology similar to that used in a cell phone that enables such devices, e.g., computers, to send and receive data indoors and out; anywhere within the range of a base station. Wi-Fi networks use radio technologies called IEEE 802.11 (a, b, g, n, ac, ag, etc.) to provide secure, reliable, fast wireless connectivity. A Wi-Fi network can be used to connect computers to each other, to the Internet, and to wired networks (which can use IEEE 802.3 or Ethernet). Wi-Fi networks operate in the unlicensed 2.4 and 5 GHz radio bands for example or with products that contain both bands (dual band), so the networks can provide real-world performance similar to the basic 10BaseT wired Ethernet networks used in many offices.

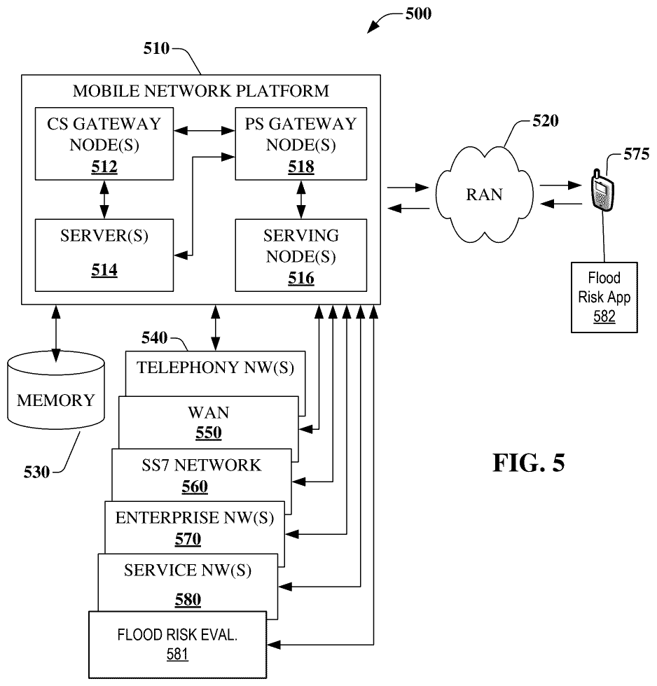

Turning now to FIG. 5, an embodiment 500 of a mobile network platform 510 is shown that is an example of network elements 150, 152, 154, 156, and/or VNEs 330, 332, 334, etc. For example, platform 510 can facilitate in whole or in part determining climate-compensated precipitation data, estimating inland flood depths of a region based on the precipitation data and local terrain data, and classifying the inland flood depths according to risk scores to obtain a risk score map of the region. The risk scores and/or labels based on the risk scores can be shared with facility planning and/or maintenance organizations to inform them of pluvial flood risks associated with changing climate conditions. The classified risk scores and/or labels are easily interpretable to inform planners of short and/or long-term events. In one or more embodiments, the mobile network platform 510 can generate and receive signals transmitted and received by base stations or access points such as base station or access point 122. Generally, mobile network platform 510 can comprise components, e.g., nodes, gateways, interfaces, servers, or disparate platforms, that facilitate both packet-switched (PS) (e.g., internet protocol (IP), frame relay, asynchronous transfer mode (ATM)) and circuit-switched (CS) traffic (e.g., voice and data), as well as control generation for networked wireless telecommunication. As a non-limiting example, mobile network platform 510 can be included in telecommunications carrier networks and can be considered carrier-side components as discussed elsewhere herein. Mobile network platform 510 comprises CS gateway node(s) 512 which can interface CS traffic received from legacy networks like telephony network(s) 540 (e.g., public switched telephone network (PSTN), or public land mobile network (PLMN)) or a signaling system #7 (SS7) network 560. CS gateway node(s) 512 can authorize and authenticate traffic (e.g., voice) arising from such networks. Additionally, CS gateway node(s) 512 can access mobility, or roaming, data generated through SS7 network 560; for instance, mobility data stored in a visited location register (VLR), which can reside in memory 530. Moreover, CS gateway node(s) 512 interfaces CS-based traffic and signaling and PS gateway node(s) 518. As an example, in a 3GPP UMTS network, CS gateway node(s) 512 can be realized at least in part in gateway GPRS support node(s) (GGSN). It should be appreciated that functionality and specific operation of CS gateway node(s) 512, PS gateway node(s) 518, and serving node(s) 516, is provided and dictated by radio technology(ies) utilized by mobile network platform 510 for telecommunication over a radio access network 520 with other devices, such as a radiotelephone 575. The example radiotelephone 575 may include one or more programs, e.g., application programs 582, configured to facilitate access to flood-risk evaluation data as may be obtained via the climate and/or weather-related networks 581 and/or any of the example flood risk evaluation systems 180, 200, 220, 230.

In addition to receiving and processing CS-switched traffic and signaling, PS gateway node(s) 518 can authorize and authenticate PS-based data sessions with served mobile devices. Data sessions can comprise traffic, or content(s), exchanged with networks external to the mobile network platform 510, like wide area network(s) (WANs) 550, enterprise network(s) 570, service network(s) 580, and climate and/or weather related networks 581, which can be embodied in local area network(s) (LANs), can also be interfaced with mobile network platform 510 through PS gateway node(s) 518. It is to be noted that WANs 550 and enterprise network(s) 570 can embody, at least in part, a service network(s) like IP multimedia subsystem (IMS). Based on radio technology layer(s) available in technology resource(s) or radio access network 520, PS gateway node(s) 518 can generate packet data protocol contexts when a data session is established; other data structures that facilitate routing of packetized data also can be generated. To that end, in an aspect, PS gateway node(s) 518 can comprise a tunnel interface (e.g., tunnel termination gateway (TTG) in 3GPP UMTS network(s) (not shown)) which can facilitate packetized communication with disparate wireless network(s), such as Wi-Fi networks.

In embodiment 500, mobile network platform 510 also comprises serving node(s) 516 that, based upon available radio technology layer(s) within technology resource(s) in the radio access network 520, convey the various packetized flows of data streams received through PS gateway node(s) 518. It is to be noted that for technology resource(s) that rely primarily on CS communication, server node(s) can deliver traffic without reliance on PS gateway node(s) 518; for example, server node(s) can embody at least in part a mobile switching center. As an example, in a 3GPP UMTS network, serving node(s) 516 can be embodied in serving GPRS support node(s) (SGSN).

For radio technologies that exploit packetized communication, server(s) 514 in mobile network platform 510 can execute numerous applications that can generate multiple disparate packetized data streams or flows, and manage (e.g., schedule, queue, format . . . ) such flows. Such application(s) can comprise add-on features to standard services (for example, provisioning, billing, customer support . . . ) provided by mobile network platform 510. Data streams (e.g., content(s) that are part of a voice call or data session) can be conveyed to PS gateway node(s) 518 for authorization/authentication and initiation of a data session, and to serving node(s) 516 for communication thereafter. In addition to application server, server(s) 514 can comprise utility server(s), a utility server can comprise a provisioning server, an operations and maintenance server, a security server that can implement at least in part a certificate authority and firewalls as well as other security mechanisms, and the like. In an aspect, security server(s) secure communication served through mobile network platform 510 to ensure network's operation and data integrity in addition to authorization and authentication procedures that CS gateway node(s) 512 and PS gateway node(s) 518 can enact. Moreover, provisioning server(s) can provision services from external network(s) like networks operated by a disparate service provider; for instance, WAN 550 or Global Positioning System (GPS) network(s) (not shown). Provisioning server(s) can also provision coverage through networks associated with mobile network platform 510 (e.g., deployed and operated by the same service provider), such as the distributed antennas networks shown in FIG. 1(s) that enhance wireless service coverage by providing more network coverage.

It is to be noted that server(s) 514 can comprise one or more processors configured to confer at least in part the functionality of mobile network platform 510. To that end, the one or more processors can execute code instructions stored in memory 530, for example. It should be appreciated that server(s) 514 can comprise a content manager, which operates in substantially the same manner as described hereinbefore.

In example embodiment 500, memory 530 can store information related to operation of mobile network platform 510. Other operational information can comprise provisioning information of mobile devices served through mobile network platform 510, subscriber databases; application intelligence, pricing schemes, e.g., promotional rates, flat-rate programs, couponing campaigns; technical specification(s) consistent with telecommunication protocols for operation of disparate radio, or wireless, technology layers; and so forth. Memory 530 can also store information from at least one of telephony network(s) 540, WAN 550, SS7 network 560, or enterprise network(s) 570. In an aspect, memory 530 can be, for example, accessed as part of a data store component or as a remotely connected memory store.

In order to provide a context for the various aspects of the disclosed subject matter, FIG. 5, and the following discussion, are intended to provide a brief, general description of a suitable environment in which the various aspects of the disclosed subject matter can be implemented. While the subject matter has been described above in the general context of computer-executable instructions of a computer program that runs on a computer and/or computers, those skilled in the art will recognize that the disclosed subject matter also can be implemented in combination with other program modules. Generally, program modules comprise routines, programs, components, data structures, etc., that perform particular tasks and/or implement particular abstract data types.

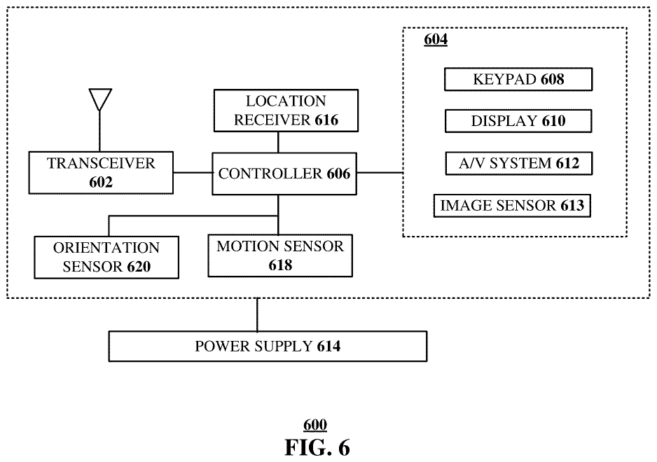

Turning now to FIG. 6, an illustrative embodiment of a communication device 600 is shown. The communication device 600 can serve as an illustrative embodiment of devices such as data terminals 114, mobile devices 124, vehicle 126, display devices 144 or other client devices for communication via either communications network 125. For example, computing device 600 can facilitate in whole or in part determining climate-compensated precipitation data, estimating inland flood depths of a region based on the precipitation data and local terrain data, and classifying the inland flood depths according to risk scores to obtain a risk score map of the region. The risk scores and/or labels based on the risk scores can be shared with facility planning and/or maintenance organizations to inform them of pluvial flood risks associated with changing climate conditions. The classified risk scores and/or labels are easily interpretable to inform planners of short and/or long-term events.

The communication device 600 can comprise a wireline and/or wireless transceiver 602 (herein transceiver 602), a user interface (UI) 604, a power supply 614, a location receiver 616, a motion sensor 618, an orientation sensor 620, and a controller 606 for managing operations thereof. The transceiver 602 can support short-range or long-range wireless access technologies such as Bluetooth®, ZigBee®, Wi-Fi, DECT, or cellular communication technologies, just to mention a few (Bluetooth® and ZigBee® are trademarks registered by the Bluetooth® Special Interest Group and the ZigBee® Alliance, respectively). Cellular technologies can include, for example, CDMA-1X, UMTS/HSDPA, GSM/GPRS, TDMA/EDGE, EV/DO, WiMAX, SDR, LTE, as well as other next generation wireless communication technologies as they arise. The transceiver 602 can also be adapted to support circuit-switched wireline access technologies (such as PSTN), packet-switched wireline access technologies (such as TCP/IP, VoIP, etc.), and combinations thereof.

The UI 604 can include a depressible or touch-sensitive keypad 608 with a navigation mechanism such as a roller ball, a joystick, a mouse, or a navigation disk for manipulating operations of the communication device 600. The keypad 608 can be an integral part of a housing assembly of the communication device 600 or an independent device operably coupled thereto by a tethered wireline interface (such as a USB cable) or a wireless interface supporting for example Bluetooth®. The keypad 608 can represent a numeric keypad commonly used by phones, and/or a QWERTY keypad with alphanumeric keys. The UI 604 can further include a display 610 such as monochrome or color LCD (Liquid Crystal Display), OLED (Organic Light Emitting Diode) or other suitable display technology for conveying images to an end user of the communication device 600. In an embodiment where the display 610 is touch-sensitive, a portion or all of the keypad 608 can be presented by way of the display 610 with navigation features.

The display 610 can use touch screen technology to also serve as a user interface for detecting user input. As a touch screen display, the communication device 600 can be adapted to present a user interface having graphical user interface (GUI) elements that can be selected by a user with a touch of a finger. The display 610 can be equipped with capacitive, resistive or other forms of sensing technology to detect how much surface area of a user's finger has been placed on a portion of the touch screen display. This sensing information can be used to control the manipulation of the GUI elements or other functions of the user interface. The display 610 can be an integral part of the housing assembly of the communication device 600 or an independent device communicatively coupled thereto by a tethered wireline interface (such as a cable) or a wireless interface.

The UI 604 can also include an audio system 612 that utilizes audio technology for conveying low volume audio (such as audio heard in proximity of a human ear) and high-volume audio (such as speakerphone for hands free operation). The audio system 612 can further include a microphone for receiving audible signals of an end user. The audio system 612 can also be used for voice recognition applications. The UI 604 can further include an image sensor 613 such as a charged coupled device (CCD) camera for capturing still or moving images.

The power supply 614 can utilize common power management technologies such as replaceable and rechargeable batteries, supply regulation technologies, and/or charging system technologies for supplying energy to the components of the communication device 600 to facilitate long-range or short-range portable communications. Alternatively, or in combination, the charging system can utilize external power sources such as DC power supplied over a physical interface such as a USB port or other suitable tethering technologies.

The location receiver 616 can utilize location technology such as a global positioning system (GPS) receiver capable of assisted GPS for identifying a location of the communication device 600 based on signals generated by a constellation of GPS satellites, which can be used for facilitating location services such as navigation. The motion sensor 618 can utilize motion sensing technology such as an accelerometer, a gyroscope, or other suitable motion sensing technology to detect motion of the communication device 600 in three-dimensional space. The orientation sensor 620 can utilize orientation sensing technology such as a magnetometer to detect the orientation of the communication device 600 (north, south, west, and east, as well as combined orientations in degrees, minutes, or other suitable orientation metrics).

The communication device 600 can use the transceiver 602 to also determine a proximity to a cellular, Wi-Fi, Bluetooth®, or other wireless access points by sensing techniques such as utilizing a received signal strength indicator (RSSI) and/or signal time of arrival (TOA) or time of flight (TOF) measurements. The controller 606 can utilize computing technologies such as a microprocessor, a digital signal processor (DSP), programmable gate arrays, application specific integrated circuits, and/or a video processor with associated storage memory such as Flash, ROM, RAM, SRAM, DRAM or other storage technologies for executing computer instructions, controlling, and processing data supplied by the aforementioned components of the communication device 600.

Other components not shown in FIG. 6 can be used in one or more embodiments of the subject disclosure. For instance, the communication device 600 can include a slot for adding or removing an identity module such as a Subscriber Identity Module (SIM) card or Universal Integrated Circuit Card (UICC). SIM or UICC cards can be used for identifying subscriber services, executing programs, storing subscriber data, and so on.

It may be appreciated that the various systems, devices, processes, and software techniques disclosed herein provide value to various organizations, government agencies, communities and individuals by enabling informed climate risk assessments. In particular, the disclosure enables practical applications of data made available for publicly reported climate disclosures in formats that can be readily interpreted and enacted upon with little to no requirement for specialized training. For example, impacts of climate change obtained according to the illustrative techniques can be provided in the form of informational reporting and/or recommendations tailored and/or otherwise adapted based on an intended use, application and/or consumer. Such tailoring may take into consideration business rules, policies, economic factors, personal safety, demographics, construction practices, and so on. Accordingly, the disclosed techniques can be applied to add resiliency to businesses and/or communities in the face of otherwise uncertain impacts resulting from changing climate conditions.

By way of example, a climate-informed business strategy can support satisfaction of service level agreements (SLAs) for a business and/or commercial activity. It is common for communications and/or network service providers to operate according to SLAs that impose an availability and/or “uptime” requirement. These requirements can be challenging, e.g., requiring that a system and/or service be available up to 99.9999% of the time—virtually all the time. Ensuring such requirements can be costly as are implications should they fail to meet such requirements. The techniques disclosed herein permit businesses and/or government organizations to achieve a better assessment of pluvial flooding impacts in the context of a changing climate. It is also understood that by quantifying such risks, planners can address solutions in an informed and efficient, e.g., cost effective, manner, in an effort to reduce any impact resulting from disaster recovery and to thereby preserve revenue by reducing potential damage and/or loss of customers, e.g., “churn.”

The example embodiments including the various systems, devices processes and/or techniques disclosed herein have the potential to be offered and/or otherwise provided as a service. Such flood risk evaluation services would be valuable to corporations, utilities, and municipalities, e.g., for risk assessment of infrastructure using forward-looking climate data. It is understood that a flood risk service can be easily built into existing processes that can lead to cost savings from proactive action and improved safety of the locations being analyzed, e.g., to reduce the cost of flooding induced impact by providing higher precision results than existing approaches and presenting the results in an easy and/or intuitive manner to facilitate adoption by facility planners and the like.

The terms “first,” “second,” “third,” and so forth, as used in the claims, unless otherwise clear by context, is for clarity only and does not otherwise indicate or imply any order in time. For instance, “a first determination,” “a second determination,” and “a third determination,” does not indicate or imply that the first determination is to be made before the second determination, or vice versa, etc.

In the subject specification, terms such as “store,” “storage,” “data store,” data storage,” “database,” and substantially any other information storage component relevant to operation and functionality of a component, refer to “memory components,” or entities embodied in a “memory” or components comprising the memory. It will be appreciated that the memory components described herein can be either volatile memory or non-volatile memory, or can comprise both volatile and nonvolatile memory, by way of illustration, and not limitation, volatile memory, non-volatile memory, disk storage, and memory storage. Further, nonvolatile memory can be included in read only memory (ROM), programmable ROM (PROM), electrically programmable ROM (EPROM), electrically erasable ROM (EEPROM), or flash memory. Volatile memory can comprise random access memory (RAM), which acts as external cache memory. By way of illustration and not limitation, RAM is available in many forms such as synchronous RAM (SRAM), dynamic RAM (DRAM), synchronous DRAM (SDRAM), double data rate SDRAM (DDR SDRAM), enhanced SDRAM (ESDRAM), Synchlink DRAM (SLDRAM), and direct Rambus RAM (DRRAM). Additionally, the disclosed memory components of systems or methods herein are intended to comprise, without being limited to comprising, these and any other suitable types of memory.

Moreover, it will be noted that the disclosed subject matter can be practiced with other computer system configurations, comprising single-processor or multiprocessor computer systems, mini-computing devices, mainframe computers, as well as personal computers, hand-held computing devices (e.g., PDA, phone, smartphone, watch, tablet computers, netbook computers, etc.), microprocessor-based or programmable consumer or industrial electronics, and the like. The illustrated aspects can also be practiced in distributed computing environments where tasks are performed by remote processing devices that are linked through a communications network; however, some if not all aspects of the subject disclosure can be practiced on stand-alone computers. In a distributed computing environment, program modules can be located in both local and remote memory storage devices.

In one or more embodiments, information regarding use of services can be generated including services being accessed, media consumption history, user preferences, and so forth. This information can be obtained by various methods including user input, detecting types of communications (e.g., video content vs. audio content), analysis of content streams, sampling, and so forth. The generating, obtaining and/or monitoring of this information can be responsive to an authorization provided by the user. In one or more embodiments, an analysis of data can be subject to authorization from user(s) associated with the data, such as an opt-in, an opt-out, acknowledgement requirements, notifications, selective authorization based on types of data, and so forth.

Some of the embodiments described herein can also employ artificial intelligence (AI) to facilitate automating one or more features described herein, such as risk evaluation of climate-adjusted weather data, and/or conversion of flood depth data into risk metric data, and/or assignment of risk labels to risk scores, and/or determination of recommendations, e.g., action plans. The embodiments (e.g., in connection with automatically identifying acquired cell sites that provide a maximum value/benefit after addition to an existing communication network) can employ various AI-based schemes for carrying out various embodiments thereof. Moreover, the classifier can be employed to determine a ranking or priority of each cell site of the acquired network. A classifier is a function that maps an input attribute vector, x=(x₁, x₂, x₃, x₄ . . . xₙ), to a confidence that the input belongs to a class, that is, f(x)=confidence (class). Such classification can employ a probabilistic and/or statistical-based analysis (e.g., factoring into the analysis utilities and costs) to determine or infer an action that a user desires to be automatically performed. A support vector machine (SVM) is an example of a classifier that can be employed. The SVM operates by finding a hypersurface in the space of possible inputs, which the hypersurface attempts to split the triggering criteria from the non-triggering events. Intuitively, this makes the classification correct for testing data that is near, but not identical to training data. Other directed and undirected model classification approaches comprise, e.g., naïve Bayes, Bayesian networks, decision trees, neural networks, fuzzy logic models, and probabilistic classification models providing different patterns of independence can be employed. Classification as used herein also is inclusive of statistical regression that is utilized to develop models of priority.

As will be readily appreciated, one or more of the embodiments can employ classifiers that are explicitly trained (e.g., via a generic training data) as well as implicitly trained (e.g., via observing UE behavior, operator preferences, historical information, receiving extrinsic information). For example, SVMs can be configured via a learning or training phase within a classifier constructor and feature selection module. Thus, the classifier(s) can be used to automatically learn and perform a number of functions, including but not limited to determining according to predetermined criteria which of the acquired cell sites will benefit a maximum number of subscribers and/or which of the acquired cell sites will add minimum value to the existing communication network coverage, etc.

As used in some contexts in this application, in some embodiments, the terms “component,” “system” and the like are intended to refer to, or comprise, a computer-related entity or an entity related to an operational apparatus with one or more specific functionalities, wherein the entity can be either hardware, a combination of hardware and software, software, or software in execution. As an example, a component may be, but is not limited to being, a process running on a processor, a processor, an object, an executable, a thread of execution, computer-executable instructions, a program, and/or a computer. By way of illustration and not limitation, both an application running on a server and the server can be a component. One or more components may reside within a process and/or thread of execution and a component may be localized on one computer and/or distributed between two or more computers. In addition, these components can execute from various computer readable media having various data structures stored thereon. The components may communicate via local and/or remote processes such as in accordance with a signal having one or more data packets (e.g., data from one component interacting with another component in a local system, distributed system, and/or across a network such as the Internet with other systems via the signal). As another example, a component can be an apparatus with specific functionality provided by mechanical parts operated by electric or electronic circuitry, which is operated by a software or firmware application executed by a processor, wherein the processor can be internal or external to the apparatus and executes at least a part of the software or firmware application. As yet another example, a component can be an apparatus that provides specific functionality through electronic components without mechanical parts, the electronic components can comprise a processor therein to execute software or firmware that confers at least in part the functionality of the electronic components. While various components have been illustrated as separate components, it will be appreciated that multiple components can be implemented as a single component, or a single component can be implemented as multiple components, without departing from example embodiments.

Further, the various embodiments can be implemented as a method, apparatus or article of manufacture using standard programming and/or engineering techniques to produce software, firmware, hardware or any combination thereof to control a computer to implement the disclosed subject matter. The term “article of manufacture” as used herein is intended to encompass a computer program accessible from any computer-readable device or computer-readable storage/communications media. For example, computer readable storage media can include, but are not limited to, magnetic storage devices (e.g., hard disk, floppy disk, magnetic strips), optical disks (e.g., compact disk (CD), digital versatile disk (DVD)), smart cards, and flash memory devices (e.g., card, stick, key drive). Of course, those skilled in the art will recognize many modifications can be made to this configuration without departing from the scope or spirit of the various embodiments.

In addition, the words “example” and “exemplary” are used herein to mean serving as an instance or illustration. Any embodiment or design described herein as “example” or “exemplary” is not necessarily to be construed as preferred or advantageous over other embodiments or designs. Rather, use of the word example or exemplary is intended to present concepts in a concrete fashion. As used in this application, the term “or” is intended to mean an inclusive “or” rather than an exclusive “or.” That is, unless specified otherwise or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more” unless specified otherwise or clear from context to be directed to a singular form.

Moreover, terms such as “user equipment,” “mobile station,” “mobile,” subscriber station,” “access terminal,” “terminal,” “handset,” “mobile device” (and/or terms representing similar terminology) can refer to a wireless device utilized by a subscriber or user of a wireless communication service to receive or convey data, control, voice, video, sound, gaming or substantially any data-stream or signaling-stream. The foregoing terms are utilized interchangeably herein and with reference to the related drawings.

Furthermore, the terms “user,” “subscriber,” “customer,” “consumer” and the like are employed interchangeably throughout, unless context warrants particular distinctions among the terms. It should be appreciated that such terms can refer to human entities or automated components supported through artificial intelligence (e.g., a capacity to make inference based, at least, on complex mathematical formalisms), which can provide simulated vision, sound recognition and so forth.

As employed herein, the term “processor” can refer to substantially any computing processing unit or device comprising, but not limited to comprising, single-core processors; single-processors with software multithread execution capability; multi-core processors; multi-core processors with software multithread execution capability; multi-core processors with hardware multithread technology; parallel platforms; and parallel platforms with distributed shared memory. Additionally, a processor can refer to an integrated circuit, an application specific integrated circuit (ASIC), a digital signal processor (DSP), a field programmable gate array (FPGA), a programmable logic controller (PLC), a complex programmable logic device (CPLD), a discrete gate or transistor logic, discrete hardware components or any combination thereof designed to perform the functions described herein. Processors can exploit nano-scale architectures such as, but not limited to, molecular and quantum-dot based transistors, switches and gates, in order to optimize space usage or enhance performance of user equipment. A processor can also be implemented as a combination of computing processing units.

As used herein, terms such as “data storage,” data storage,” “database,” and substantially any other information storage component relevant to operation and functionality of a component, refer to “memory components,” or entities embodied in a “memory” or components comprising the memory. It will be appreciated that the memory components or computer-readable storage media, described herein can be either volatile memory or nonvolatile memory or can include both volatile and nonvolatile memory.

What has been described above includes mere examples of various embodiments. It is, of course, not possible to describe every conceivable combination of components or methodologies for purposes of describing these examples, but one of ordinary skill in the art can recognize that many further combinations and permutations of the present embodiments are possible. Accordingly, the embodiments disclosed and/or claimed herein are intended to embrace all such alterations, modifications and variations that fall within the spirit and scope of the appended claims. Furthermore, to the extent that the term “includes” is used in either the detailed description or the claims, such term is intended to be inclusive in a manner similar to the term “comprising” as “comprising” is interpreted when employed as a transitional word in a claim.

In addition, a flow diagram may include a “start” and/or “continue” indication. The “start” and “continue” indications reflect that the steps presented can optionally be incorporated in or otherwise used in conjunction with other routines. In this context, “start” indicates the beginning of the first step presented and may be preceded by other activities not specifically shown. Further, the “continue” indication reflects that the steps presented may be performed multiple times and/or may be succeeded by other activities not specifically shown. Further, while a flow diagram indicates a particular ordering of steps, other orderings are likewise possible provided that the principles of causality are maintained.

As may also be used herein, the term(s) “operably coupled to,” “coupled to,” and/or “coupling” includes direct coupling between items and/or indirect coupling between items via one or more intervening items. Such items and intervening items include, but are not limited to, junctions, communication paths, components, circuit elements, circuits, functional blocks, and/or devices. As an example of indirect coupling, a signal conveyed from a first item to a second item may be modified by one or more intervening items by modifying the form, nature or format of information in a signal, while one or more elements of the information in the signal are nevertheless conveyed in a manner than can be recognized by the second item. In a further example of indirect coupling, an action in a first item can cause a reaction on the second item, as a result of actions and/or reactions in one or more intervening items.

Although specific embodiments have been illustrated and described herein, it should be appreciated that any arrangement which achieves the same or similar purpose may be substituted for the embodiments described or shown by the subject disclosure. The subject disclosure is intended to cover any and all adaptations or variations of various embodiments. Combinations of the above embodiments, and other embodiments not specifically described herein, can be used in the subject disclosure. For instance, one or more features from one or more embodiments can be combined with one or more features of one or more other embodiments. In one or more embodiments, features that are positively recited can also be negatively recited and excluded from the embodiment with or without replacement by another structural and/or functional feature. The steps or functions described with respect to the embodiments of the subject disclosure can be performed in any order. The steps or functions described with respect to the embodiments of the subject disclosure can be performed alone or in combination with other steps or functions of the subject disclosure, as well as from other embodiments or from other steps that have not been described in the subject disclosure. Further, more than or less than all of the features described with respect to an embodiment can also be utilized.

What is claimed is:

1. A flood-risk evaluation system, comprising:
a processing system including a processor; and
a memory that stores executable instructions that, when executed by the processing system, facilitate performance of operations, the operations comprising:
receiving dynamically downscaled climate data associated with a geographic region and comprising precipitation data determined according to a climate model;
receiving local topographical data of the geographic region;
determining inundation depth data associated with the geographic region, based on the local topographical data and the precipitation data determined according to the climate model;
classifying the inundation depth data according to a risk score to obtain a risk score map of the geographic region; and
assigning a risk label map associated with the geographic region and based on the risk score map, wherein the risk label map facilitates a facility planning activity of a facility located within the geographic region.

2. The flood-risk evaluation system of claim 1, wherein the determining the inundation depth data further comprises:
performing a hydrologic analysis based on the precipitation data and the local topographical data.

3. The flood-risk evaluation system of claim 2, wherein the operations further comprise:
determining an environmental condition of the geographic region according to a comprehensive environmental water model, wherein the hydrologic analysis is further based on the comprehensive environmental water model.

4. The flood-risk evaluation system of claim 1, wherein the operations further comprise:
determining a future estimate of greenhouse gas emissions; and
determining a climate model based on the future estimate of greenhouse gas emissions, wherein the dynamically downscaled climate data is obtained from global climate forecast data obtained determined according to the climate model.

5. The flood-risk evaluation system of claim 1, wherein the inundation depth data relates to a future state inundation state of the geographic region.

6. The flood-risk evaluation system of claim 5, wherein the operations further comprise:
identifying a short-term precipitation forecast associated with the geographic region; and
adjusting the short-term precipitation forecast according to the precipitation data determined according to the climate model to obtain an adjusted precipitation forecast.

7. The flood-risk evaluation system of claim 6, wherein the determining the inundation depth data is based on the adjusted precipitation forecast.

8. The flood-risk evaluation system of claim 1, wherein the operations further comprise:
associating inundation depth data with grid elements of a grid map overlay, wherein the risk score map comprises risk scores allocated to grid elements of the grid map overlay.

9. The flood-risk evaluation system of claim 1, wherein the operations further comprise:
determining a recommendation based on the risk score map, the risk label map, or a combination thereof, wherein the recommendation corresponds to the facility planning activity.

10. The flood-risk evaluation system of claim 1, wherein the operations further comprise:
identifying a Federal Emergency Management Agency (FEMA) flood risk map associated with the geographic region, wherein the classifying the inundation depth data according to the risk score is based on the FEMA flood risk map.

11. A method of evaluating a flood risk, comprising:
obtaining, by a processing system including a processor, dynamically downscaled climate data associated with a geographic region and comprising precipitation data determined according to a climate model;
obtaining, by the processing system, terrain data of the geographic region;
determining, by the processing system, inundation depth data associated with the geographic region, based on the terrain data and the precipitation data determined according to the climate model;
scoring, by the processing system, the inundation depth data to obtain a risk score map of the geographic region; and
assigning, by the processing system, a risk label map associated with the geographic region and based on the risk score map, wherein the risk label map facilitates a facility planning activity of a facility located within the geographic region.

12. The method of evaluating a flood risk of claim 11, further comprising:
performing, by the processing system, a hydrologic analysis based on the precipitation data and the terrain data.

13. The method of evaluating a flood risk of claim 11, further comprising:
determining, by the processing system, a future estimate of greenhouse gas emissions; and
determining, by the processing system, a climate model based on the future estimate of greenhouse gas emissions, wherein the dynamically downscaled climate data is obtained from global climate forecast data obtained determined according to the climate model.

14. The method of evaluating a flood risk of claim 11, further comprising:
identifying, by the processing system, a short-term precipitation forecast associated with the geographic region; and
adjusting, by the processing system, the short-term precipitation forecast according to the precipitation data determined according to the climate model to obtain an adjusted precipitation forecast.

15. The method of evaluating a flood risk of claim 14, wherein the determining the inundation depth data is based on the adjusted precipitation forecast.

16. The method of evaluating a flood risk of claim 11, further comprising:
identifying, by the processing system, a Federal Emergency Management Agency (FEMA) flood risk map associated with the geographic region, wherein the scoring the inundation depth data is further based on the FEMA flood risk map.

17. The method of evaluating a flood risk of claim 11, further comprising:
determining, by the processing system, a recommendation based on the risk score map, the risk label map, or a combination thereof, wherein the recommendation corresponds to the facility planning activity.

18. A non-transitory machine-readable medium, comprising executable instructions that, when executed by a processing system including a processor, facilitate performance of operations, the operations comprising:
identifying dynamically downscaled climate data associated with a geographic region and comprising precipitation data determined according to a climate model;
obtaining terrain data of the geographic region;
determining flood-depth data associated with the geographic region, based on the terrain data and the precipitation data determined according to the climate model;
evaluating the flood-depth data according to a scoring methodology to obtain flood-depth risk data of the geographic region; and
assigning risk label data according to the flood-depth risk data to obtain a risk label map, wherein the risk label map facilitates a planning activity within the geographic region.

19. The non-transitory machine-readable medium of claim 18, wherein the operations further comprise:
identifying a short-term precipitation forecast associated with the geographic region; and
adjusting, by the processing system, the short-term precipitation forecast according to the precipitation data determined according to the climate model to obtain an adjusted precipitation forecast.

20. The non-transitory machine-readable medium of claim 19, wherein the determining the flood-depth data is based on the adjusted precipitation forecast.
